(19) United States
(12) Patent Application Publication
(10) Pub. No.: US 2025/0022798 A1
(43) Pub. Date: Jan. 16, 2025

(54) SEMICONDUCTOR DEVICE AND ELECTRONIC SYSTEM INCLUDING SEMICONDUCTOR DEVICE

(71) Applicant: Samsung Electronics Co., Ltd., Suwon-si (KR)

(72) Inventors: HAKSEON KIM, Suwon-si (KR); DONGJIN LEE, Suwon-si (KR); JAEDUK LEE, Suwon-si (KR); KANG-OH YUN, Suwon-si (KR)

(21) Appl. No.: 18/441,071

(22) Filed: Feb. 14, 2024

(30) Foreign Application Priority Data
Jul. 11, 2023 (KR) 10-2023-0089894

(51) Int. Cl. H01L 23/528; H01L 23/522; H01L 25/065; H10B 41/10; H10B 41/27; H10B 41/35; H10B 41/40; H10B 43/10; H10B 43/27; H10B 43/35; H10B 43/40; H10B 80/00

(52) U.S. Cl. CPC H01L 23/5283; H01L 23/5226; H01L 25/0652; H10B 41/10; H10B 41/27; H10B 41/35; H10B 41/40; H10B 43/10; H10B 43/27; H10B 43/35; H10B 43/40; H10B 80/00; H01L 2225/06506

(57) ABSTRACT

According to an aspect of the present disclosure, a semiconductor device includes a peripheral structure, and a cell structure stacked on the peripheral structure. The cell structure includes a first substrate including a pad region and a cell region including a cell array region and an extending region, wherein the first substrate includes a first surface and a second surface opposite to the first surface, and wherein second surface faces the peripheral structure, a gate stacking structure including a plurality of gate electrodes and a plurality of interlayer insulating layers alternately stacked on the second surface of the first substrate, a channel structure disposed on the cell array region and penetrating the plurality of gate electrodes and the plurality of interlayer insulating layers, a plurality of gate contacts disposed on the extending region and connected to the plurality of gate electrodes, respectively, a cell insulation layer positioned over the second surface of the first substrate and covering the gate stacking structure, and an input/output contact disposed on the pad region and penetrating the cell insulation layer. The peripheral structure includes a second substrate electrically connected to the first substrate, a plurality of circuit elements positioned on the second substrate, a first barrier structure positioned over the second substrate and including a plurality of lower barrier layers, a plurality of first via holes disposed on the cell region and the pad region and penetrating at least one of the plurality of lower barrier layers, a plurality of second via holes disposed on the cell region and penetrating at least one of the plurality of lower barrier layers, and a plurality of contact vias positioned within the plurality of first via holes and connected to the plurality of circuit elements. In at least one lower barrier layer of the plurality of lower barrier layers, a sum of areas of at least one of the plurality of first via holes per unit area on the pad region is equal to a sum of areas of at least one of the plurality of first via holes on the cell region and areas of the plurality of second via holes per unit area on the cell region.

### CROSS-REFERENCE TO RELATED APPLICATION

This application claims priority to and the benefit of Korean Patent Application No. 10-2023-0089894 filed on Jul. 11, 2023, in the Korean Intellectual Property Office. The entire contents of which are herein incorporated by reference.

### BACKGROUND OF THE DISCLOSURE

### 1. Field of the Disclosure

The present disclosure relates to a semiconductor device and an electronic system including a semiconductor device.

### 2. Description of the Related Art

Electronic systems with data storage include a semiconductor device capable of storing data. Methods of increasing a data storage capacity of the semiconductor device is being researched. For example, as one of the methods of increasing the data storage capacity of the semiconductor device, the semiconductor device including three-dimensionally arranged memory cells instead of two-dimensionally arranged memory cells has been proposed.

### SUMMARY

Embodiment intends to provide an electronic system including a semiconductor device and a semiconductor device that may improve performance and reliability.

According to an aspect of the present disclosure, a semiconductor device includes a peripheral structure, and a cell structure stacked on the peripheral structure. The cell structure includes a first substrate including a pad region and a cell region including a cell array region and an extending region, wherein the first substrate includes a first surface and a second surface opposite to the first surface, and wherein second surface faces the peripheral structure, a gate stacking structure including a plurality of gate electrodes and a plurality of interlayer insulating layers alternately stacked on the second surface of the first substrate, a channel structure disposed on the cell array region and penetrating the plurality of gate electrodes and the plurality of interlayer insulating layers, a plurality of gate contacts disposed on the extending region and connected to the plurality of gate electrodes, respectively, a cell insulation layer positioned over the second surface of the first substrate and covering the gate stacking structure, and an input/output contact disposed on the pad region and penetrating the cell insulation layer. The peripheral structure includes a second substrate electrically connected to the first substrate, a plurality of circuit elements positioned on the second substrate, a first barrier structure positioned over the second substrate and including a plurality of lower barrier layers, a plurality of first via holes disposed on the cell region and the pad region and penetrating at least one of the plurality of lower barrier layers, a plurality of second via holes disposed on the cell region and penetrating at least one of the plurality of lower barrier layers, and a plurality of contact vias positioned within the plurality of first via holes and connected to the plurality of circuit elements. In at least one lower barrier layer of the plurality of lower barrier layers, a sum of areas of at least one of the plurality of first via holes per unit area on the pad region is equal to a sum of areas of at least one of the plurality of first via holes on the cell region and areas of the plurality of second via holes per unit area on the cell region.

According to an aspect of the present disclosure, a semiconductor device includes a peripheral structure, and a cell structure stacked on the peripheral structure. The cell structure includes a first substrate including a pad region and a cell region including a cell array region and an extending region, wherein the first substrate includes a first surface and a second surface opposite to the first surface, and wherein the second surface faces the peripheral structure, a gate stacking structure including a plurality of gate electrodes and a plurality of interlayer insulating layers alternately stacked on the second surface of the first substrate, a channel structure disposed on the cell array region and penetrating the plurality of gate electrodes and the plurality of interlayer insulating layers, a plurality of gate contacts disposed on the extending region and connected to the plurality of gate electrodes, respectively, a cell insulation layer positioned over the second surface of the first substrate and covering the gate stacking structure, and an input/output contact disposed on the pad region and penetrating the cell insulation layer. The peripheral structure includes a second substrate electrically connected to the first substrate, a plurality of circuit elements positioned on the second substrate, a first barrier structure positioned over the second substrate and including a plurality of lower barrier layers, a plurality of first via holes disposed on the cell region and the pad region and penetrating at least one of the plurality of lower barrier layers, a plurality of second via holes disposed on the cell region and the pad region and penetrating at least one of the plurality of lower barrier layers, and a plurality of contact vias positioned within the plurality of first via holes and connected to the plurality of circuit elements. In at least one lower barrier layer of the plurality of lower barrier layers, a sum of areas of at least one of the plurality of second via holes per unit area on the cell region is greater than a sum of areas of at least one of the plurality of second via holes per unit area on the pad region.

According to an aspect of the present disclosure, an electron system includes a main substrate, a semiconductor device on the main substrate, and a controller electrically connected to the semiconductor device on the main substrate. The semiconductor device includes a peripheral structure and a cell structure stacked on the peripheral structure. The cell structure includes a first substrate including a cell region including a pad region and a cell array region and an extending region, wherein the first substrate includes a first surface and a second surface opposite to each other, and wherein the second surface faces the peripheral structure, a gate stacking structure including a plurality of gate electrodes and a plurality of interlayer insulating layers alternately stacked on the second surface of the first substrate, a channel structure disposed on the cell array region and penetrating the plurality of gate electrodes and the plurality of interlayer insulating layers, a plurality of gate contacts disposed on the extending region and connected to the plurality of gate electrodes, respectively, a cell insulation layer positioned on the second surface of the first substrate and covering the gate stacking structure, and an input/output contact disposed on the pad region and penetrating the cell insulation layer. The peripheral structure includes a second substrate electrically connected to the first substrate, a plurality of circuit elements positioned on the second substrate, a first barrier structure disposed on the second substrate and including a plurality of lower barrier layers, a plurality of first via holes disposed on the cell region and the pad region and penetrating at least one of the plurality of lower barrier layers, a plurality of second via holes disposed on the cell region and penetrating at least one of the plurality of lower barrier layers, and a plurality of contact vias positioned within the plurality of first via holes and connected to the plurality of circuit elements. In at least one lower barrier layer of the plurality of lower barrier layers, a sum of areas of at least one of the plurality of first via holes per unit area on the pad region is equal to a sum of areas of at least one of the plurality of first via holes on the cell region and areas of the plurality of second via holes per unit area on the cell region.

According to the semiconductor device according to an embodiment, the cell region and the pad region include a plurality of second via holes, and the density of the plurality of via holes on the pad region is substantially equivalent to the density of the plurality of via holes in the cell region. Accordingly, the circuit element may exhibit uniform performance, and the reliability of the semiconductor device may be improved.

### BRIEF DESCRIPTION OF THE DRAWINGS

FIG. 1 is a top plan view schematically showing a semiconductor device according to an embodiment.

FIG. 2 is a cross-sectional view schematically showing a semiconductor device according to an embodiment.

FIG. 3 is a cross-sectional view showing a channel structure of a semiconductor device according to an embodiment.

FIG. 4 is a cross-sectional view showing a channel structure of a semiconductor device according to some embodiments.

FIG. 5 is a cross-sectional view showing a first barrier structure of a semiconductor device according to an embodiment.

FIG. 6 is a partial cross-sectional view of a semiconductor device according to an embodiment.

FIG. 7 and FIG. 8 are cross-sectional views showing a first barrier structure of a semiconductor device according to some embodiments.

FIG. 9 is a top plan view schematically showing a semiconductor device according to some embodiments.

FIG. 10 to FIG. 24 are intermediate-level views for explaining a manufacturing method of a semiconductor memory device according to an embodiment.

FIG. 25 is a view schematically illustrating an electronic system including a semiconductor device according to an embodiment.

FIG. 26 is a perspective view schematically illustrating an electronic system including a semiconductor device according to an embodiment.

FIG. 27 is a cross-sectional view schematically illustrating a semiconductor package according to an embodiment.

### DETAILED DESCRIPTION

The present invention will be described more fully hereinafter with reference to the accompanying drawings, in which embodiments of the invention are shown. As those skilled in the art would realize, the described embodiments may be modified in various ways, all without departing from the spirit or scope of the present invention.

To clarify the present invention, parts that are not connected with the description will be omitted, and the same elements or equivalents are referred to by the same reference numerals throughout the specification.

Sizes and thicknesses of constituent members shown in the accompanying drawings are arbitrarily given for better understanding and ease of description. The present invention is not limited to the illustrated sizes and thicknesses. For better understanding and ease of description and/or for the simplicity of illustration, thicknesses of some layers and regions have been enlarged or exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

In the specification, the phrase “on a plane” means when an object portion is viewed from above, and the phrase “on a cross-section” means when a cross-section taken by vertically cutting an object portion is viewed from the side.

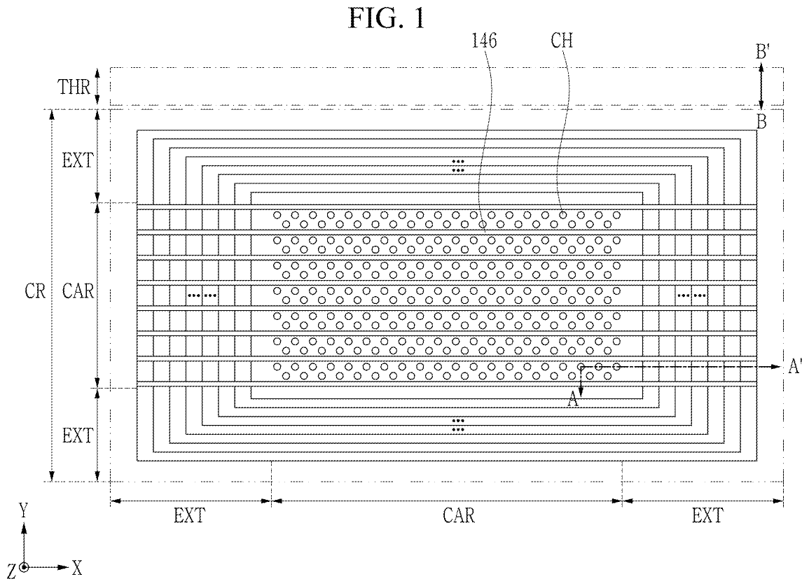

Hereinafter, a semiconductor device according to an embodiment is described in detail with reference to FIG. 1 to FIG. 5.

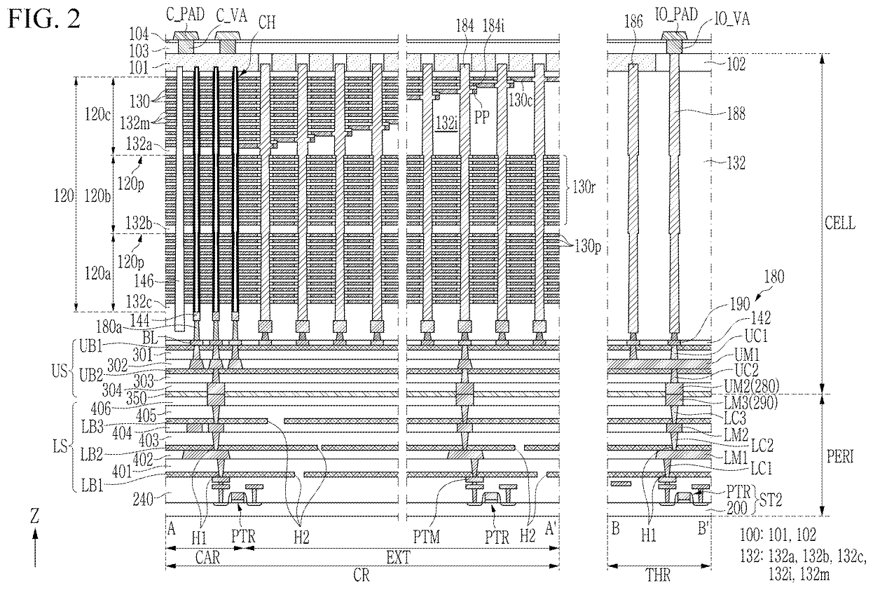

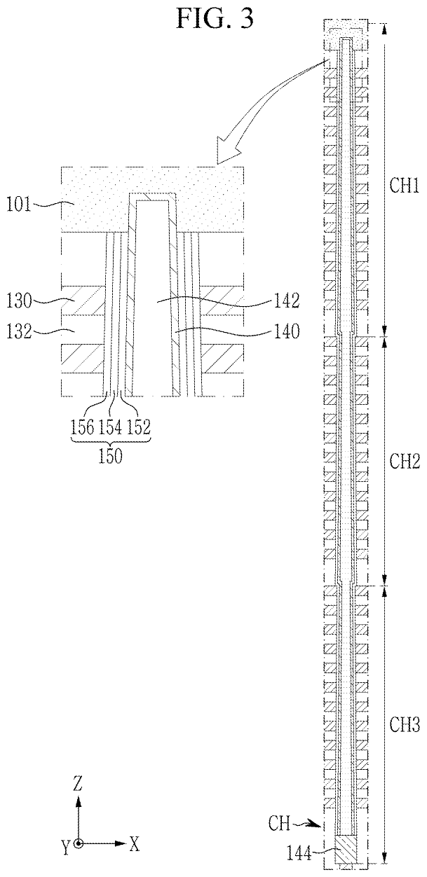

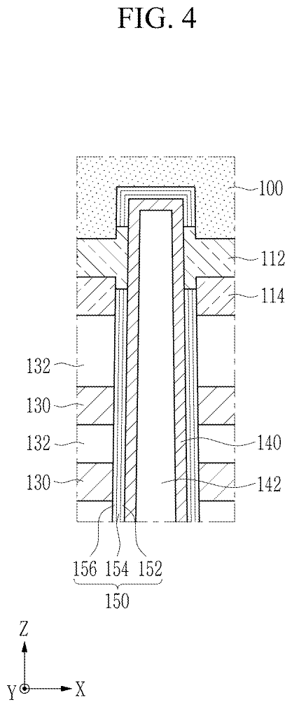

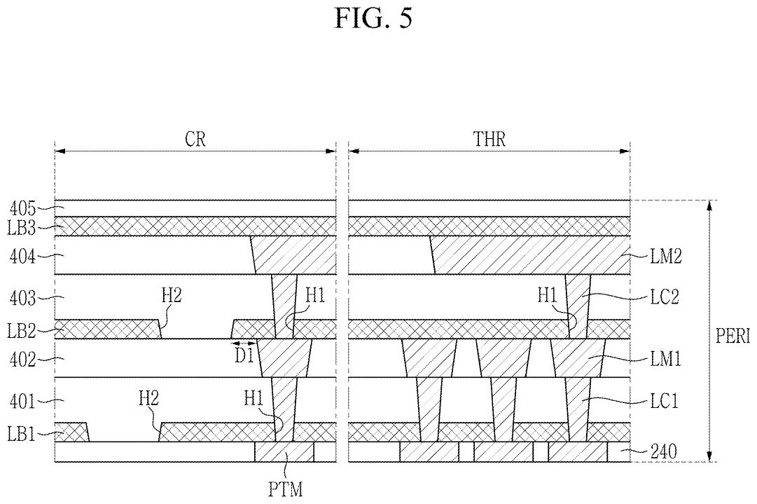

FIG. 1 is a top plan view schematically showing a semiconductor device according to an embodiment. FIG. 2 is a cross-sectional view schematically showing a semiconductor device according to an embodiment. FIG. 3 is a cross-sectional view showing a channel structure of a semiconductor device according to an embodiment. FIG. 4 is a cross-sectional view showing a channel structure of a semiconductor device according to some embodiments. FIG. 5 is a cross-sectional view showing a first barrier structure of a semiconductor device according to an embodiment.

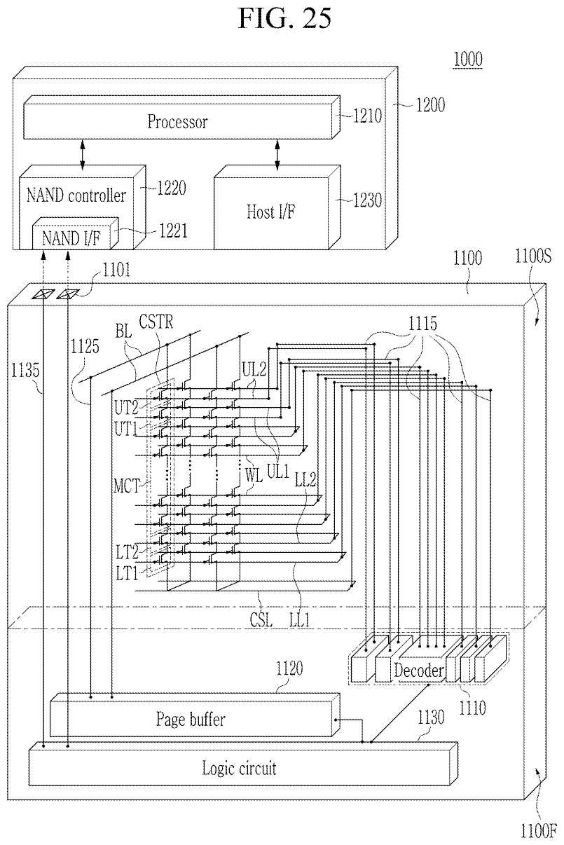

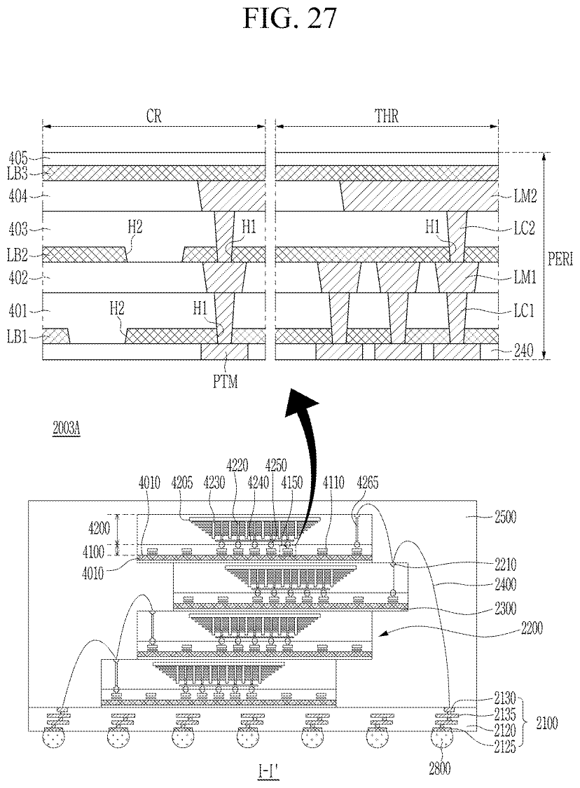

Referring to FIG. 1 and FIG. 2, a semiconductor device 10 according to an embodiment may include a cell structure CELL provided with a memory cell structure and a peri structure PERI (i.e., a peripheral structure) provided with a peripheral circuit structure for controlling an operation of the memory cell structure. In an embodiment, the cell structure CELL and the peri structure PERI may be a junction semiconductor device of a chip to chip (C2C) structure bonded by a wafer bonding method (e.g., a hybrid junction). For example, the peri structure PERI and the cell structure CELL may be parts corresponding to a first structure 1100F and a second structure 1100S of a semiconductor device 1100 included in an electronic system 1000 as shown in FIG. 25, respectively. In an embodiment, the peri structure PERI and the cell structure CELL may be a part including a first structure 4100 and a second structure 4200 of a semiconductor chip 2200 as shown in FIG. 27. The electronic system 1000 and the semiconductor chip 2200 will be described with reference to FIGS. 25 and 27, respectively.

In an embodiment, the peri structure PERI may include a peripheral circuit structure disposed on the second substrate 200, and the cell structure CELL may include a gate stacking structure 120 and a channel structure CH disposed on the cell region CR as a memory cell structure.

In an embodiment, the cell structure CELL may be positioned on the peri structure PERI. Accordingly, since it is not necessary to secure an area corresponding to the peri structure PERI separately from the cell structure CELL, the area of the semiconductor device 10 may be reduced. However, the embodiment is not limited to this and numerous variations are possible.

The semiconductor device according to an embodiment may include a cell region CR and a pad region THR. The cell region CR may include a cell array region CAR and an extending region EXT.

A memory cell array including a plurality of memory cells may be disposed on the cell array region CAR. For example, a channel structure CH, a plurality of gate electrodes 130, and a bit line BL, which will be described later, may be positioned on the cell array region CAR. In the following description, the surface of the first substrate 100 on which the memory cell array is disposed may be referred to as a front side. The surface of the first substrate 100 opposite to the front side of the first substrate 100 may be referred to as a back side of the first substrate 100.

The extending region EXT may surround the cell array region CAR. For example, the extending region EXT may surround the cell array region CAR when viewed in a plan view. On the extending region EXT, a structure or a wire to connect the gate stacking structure 120 and/or the channel structure CH positioned on the cell array region CAR to the peri structure PERI or the external circuit may be positioned.

The pad region THR may be positioned outside the extending region EXT. For example, as shown in FIG. 1, the pad region THR may be positioned on one side of the extending region EXT (e.g., one side in the second direction (a Y direction)) when viewed in a plan view. The present invention, however, is not limited thereto. On the pad region THR, a source contact 186 and an input/output contact 188 as described below may be positioned.

The cell structure CELL may include a first substrate 100, a gate stacking structure 120, a channel structure CH, a channel pad 144, a separation structure 146, a cell wire part 180, and a second barrier structure US.

The first substrate 100 may include a common source plate 101 and an insulation pattern 102. The common source plate 101 may be provided on the cell region CR and a part of the pad region THR. The common source plate 101 may be connected to the channel structure CH and the source contact 186. For example, the common source plate 101 may be connected to the channel layer 140 of the channel structure CH on the cell array region CAR. The common source plate 101 may be connected to the source contact 186 on the pad region THR. This common source plate 101 may be provided as a common source line (e.g., CSL of FIG. 25) of the non-volatile memory device. The common source plate 101 may include or may be formed of, for example, impurity doped polysilicon or metal, but it is not limited thereto.

In an embodiment, the common source plate 101 may non-overlap with the gate contact 184 and the input/output contact 188 in a third direction (a Z direction).

The insulation pattern 102 may be provided on the extending region EXT and a part of the pad region THR. The insulation pattern 102 may not be provided on the cell array region CAR. The insulation pattern 102 may be positioned around the common source plate 101. For example, the insulation pattern 102 may be positioned between one side of the common source plate 101 and the common source plate 101. The insulation pattern 102 may cover a portion of the gate contact 184 and a portion of the input/output contact 188. The insulation pattern 102 may overlap the gate contact 184 and the input/output contact 188 in the third direction (the Z direction).

The insulation pattern 102 may include or may be formed of, for example, at least one of silicon oxide, silicon nitride, silicon oxynitride, and silicon carbide, but it is not limited thereto. The insulation pattern 102, for example, may include or may be formed of Flowable oxide (FOX), Tonen Silazen (TOSZ), Undoped Silica glass (USG), Borosilica glass (BSG), PhosphoSilica glass (PSG), BoroPhosphosilica glass (BPSG), Plasma Enhanced tetra-ethyl Ortho Silicate (PE-TEOS), Fluoride silicate glass (FSG), High Density Plasma (HDP), Plasma Enhanced Oxide (PEOX), Flowable CVD (FCVD) or a combination thereof.

FIG. 2 shows that the lower surface of the insulation pattern 102 is coplanar at the lower surface and the upper surface of the common source plate 101, but it is not limited thereto. In an embodiment, the lower surface of the insulation pattern 102 may be lower than the lower surface of the common source plate 101.

The first substrate 100 may include a front surface and a back surface facing each other. The front surface of the first substrate 100 may face the peri structure PERI. In an embodiment, the front surface of the common source plate 101 and the front surface of the insulation pattern 102 may be the front surface of the first substrate 100. The rear surface of the common source plate 101 and the rear surface of the insulation pattern 102 may be rear surfaces of the first substrate 100.

A gate stacking structure 120 may be positioned on the front surface of the first substrate 100. The gate stacking structure 120 may include a plurality of cell insulation layers 132 and a plurality of gate electrodes 130 alternately stacked.

The cell insulation layer 132 may include an interlayer insulating layer 132m positioned between two adjacent gate electrodes 130 in the gate stacking structure 120 and a pad insulating part 132i positioned under the gate stacking structure 120. The cell insulation layer 132 may include a plurality of lower cell insulation layers 132a, 132b, and 132c covering each bottom surface of the plurality of gate stacking structures 120a, 120b, and 120c. The cell insulation layer 132 may be positioned on the through region THR. For a brief illustration, FIG. 2 illustrates that the cell insulation layer 132 is integrally provided without a boundary therebetween on the extending region EXT and the through region THR. However, the cell insulation layer 132 positioned on the extending region EXT and the through region THR may have various structures including one or a plurality of insulation layers. The present invention, however, is not limited thereto.

In an embodiment, the gate electrodes 130 and the interlayer insulating layers 132m of the gate stacking structure 120 may be extended and positioned to form a stair shape. For example, in a direction away from the cell array region CAR, the length of the plurality of gate electrodes 130 may sequentially increase toward the first substrate 100 to form a stair shape. In an embodiment, the plurality of gate electrodes 130 may include a portion having a stair shape in one direction or a plurality of directions. Accordingly, some of the gate electrodes 130 may extend to different lengths and have a step difference and may include a pad portion PP in which the bottom surface of each of the gate electrodes 130 is in contact with the pad insulating part 132i. The pad portion PP may mean a region where the gate contact 184 and the gate electrode 130 are in contact with each other.

The height of the gate electrode 130 in the third direction (the Z direction) contacting the gate contact 184 in the pad portion PP may be higher than the height of the other gate electrode 130 in the third direction (the Z direction). In an embodiment, the third direction (the Z direction) may be a direction perpendicular to the front surface of the first substrate 100. The contact area between the gate contact 184 and the gate electrode 130 may increase. The present invention, however, is not limited thereto.

The gate electrode 130 may include or may be formed of various conductive materials. For example, the gate electrode 130 may include or may be formed of a metallic material such as tungsten (W), copper (Cu), aluminum (Al), polysilicon, metal nitride (e.g., titanium nitride (TiN), tantalum nitride (TaN), etc.), or a combination thereof. In an embodiment, an insulating material may be further positioned outside the gate electrode 130. The cell insulation layer 132 may include or may be formed of various insulating materials. For example, the cell insulation layer 132 may include or may be formed of silicon oxide, silicon nitride, silicon oxynitride, or a low dielectric constant material having a smaller dielectric constant than silicon oxide, or a combination thereof.

The channel structure CH may be positioned within the gate stacking structure 120 of the cell array region CAR. The channel structure CH may pass through the gate stacking structure 120 and extend in a crossing direction (e.g., the third direction (the Z direction)) crossing (e.g., vertical) the first substrate 100. The channel structure CH may have a column shape. For example, the channel structure CH may have inclined sides so that the width becomes narrower as it approaches the first substrate 100 depending on an aspect ratio when viewed in a cross-section view. However, the embodiment is not limited thereto, and the structure and shape of the channel structure CH may be variously modified.

Each channel structure CHs may form one memory cell string. A plurality of channel structure CHs may form rows and columns on a plane and may be spaced apart from each other. For example, the plurality of channel structure CHs may be positioned in various forms such as a lattice form and a zigzag form on a plane. The present invention, however, is not limited thereto. In an embodiment, the arrangement and shape of the channel structure CH may be variously modified.

Referring to FIG. 3, the channel structure CH may include a channel layer 140, and a gate dielectric layer 150 positioned on the channel layer 140 between the gate electrode 130 and the channel layer 140. The channel structure CH may further include a core insulation layer 142 positioned inside (e.g., a central region) of the channel layer 140. In an embodiment, the core insulation layer 142 may be omitted.

The gate dielectric layer 150 may include a tunneling layer 152, a charge storage layer 154, and a blocking layer 156 sequentially disposed on the channel layer 140. In an embodiment, the channel structure CH may further include a channel pad 144 connected to the channel layer 140.

The channel layer 140 may include or may be formed of a semiconductor material, for example, polysilicon. The core insulation layer 142 may include or may be formed of various insulating materials. For example, the core insulation layer 142 may include or may be formed of silicon oxide, silicon nitride, silicon oxynitride, or a combination thereof. The tunneling layer 152 may include or may be formed of an insulating material capable of charge tunneling. For example, the tunneling layer 152 may include or may be formed of silicon oxide or silicon oxynitride. The charge storage layer 154 is used as a data storage region and may include or may be formed of polysilicon or silicon nitride. The blocking layer 156 may include or may be formed of an insulating material capable of preventing an undesirable charge inflow into the gate electrode 130. For example, the blocking layer 156 may include or may be formed of silicon oxide, silicon nitride, silicon oxynitride, a high dielectric constant material having a higher dielectric constant than silicon oxide, or a combination thereof.

However, the materials and stacking structure of the channel layer 140, the core insulation layer 142, and the gate dielectric layer 150 may be variously modified, and the embodiment is not limited thereto.

In an embodiment, as shown in FIG. 3, the channel structure CH may include a protruded portion toward the rear surface of the first substrate 100 rather than one surface of the gate stacking structure 120. For example, one end of the channel structure CH may be positioned between the front and rear surfaces of the common source plate 101. A portion of the gate dielectric layer 150 positioned at one end of the channel structure CH may be removed. The upper surface of the gate dielectric layer 150 may be in contact with the bottom surface of the common source plate 101. The upper surfaces of the channel layer 140 and/or the core insulation layer 142 may be positioned between the front and rear surfaces of the common source plate 101. Accordingly, the channel layer 140 may be connected to the common source plate 101 on the cell array region CAR. The upper surface of the channel layer 140 may be positioned between the front and back surfaces of the first substrate 100. For example, a part of the channel layer 140 may be provided within the common source plate 101. The upper surface and a part of the side surface of the channel layer 140 may be in contact with the common source plate 101.

The present invention, however, is not limited thereto. As shown in FIG. 4, the channel layer 140 may be connected to the horizontal conductive layers 112 and 114. In an embodiment, the cell array region CAR may further include the horizontal conductive layers 112 and 114 positioned between the first substrate 100 and the gate stacking structure 120.

The horizontal conductive layers 112 and 114 may function as a common source line by being connected to the channel structure CH. For example, the horizontal conductive layers 112 and 114 may be connected (e.g., directly connected) to the channel layer 140 of the channel structure CH. The horizontal conductive layers 112 and 114 may be electrically connected to the source contact 186.

The first and second horizontal conductive layers 112 and 114 may include or may be formed of a semiconductor material (e.g., polysilicon). For example, the first horizontal conductive layer 112 may be an impurity doped polysilicon layer, and the second horizontal conductive layer 114 may be an impurity doped polysilicon layer or a layer including impurity diffused from the first horizontal conductive layer 112. However, the embodiment is not limited thereto, and the second horizontal conductive layer 114 may be made of an insulating material. In an embodiment, the second horizontal conductive layer 114 may not be provided separately.

The channel pad 144 may be connected onto the bottom surface of the channel structure CH. The channel pad 144, for example, may be positioned on the bottom surface of the core insulation layer 142 and connected to the channel layer 140. The channel pad 144 may include or may be formed of a conductive material, for example, impurity doped polysilicon, but it is not limited thereto.

In an embodiment, the gate stacking structure 120 may include a plurality of gate stacking structures 120a, 120b, and 120c sequentially stacked on the bottom surface of the first substrate 100, and the channel structure CH may include a plurality of channel structures CH1, CH2, and CH3 penetrating the plurality of gate stacking structures 120a, 120b, and 120c. Then, since the number of stacked gate electrodes 130 may be increased, the number of memory cells may be increased with a stable structure. In the drawing, three gate stacking structures 120 are illustrated, but the embodiment is not limited thereto. Accordingly, the gate stacking structure 120 may be composed of one or two gate stacking structures, or may include four or more gate stacking structures.

The plurality of channel structures CH1, CH2, and CH3 constituting one channel structure CH may have a form connected with each other. Each of the plurality of channel structures CH1, CH2, and CH3 may have an inclined side surface such that the width becomes narrower closer to the first substrate 100 depending on an aspect ratio when viewed in a cross-section view. As shown in FIG. 3, a bent portion may be provided due to a difference in the width in a portion where the first channel structure CH1 and the second channel structure CH2 are connected with each other. In an embodiment, the plurality of channel structures CH1, CH2, and CH3 may have inclined side surfaces continuously connected with each other without a bent portion.

FIG. 2 illustrates that the gate dielectric layer 150, the channel layer 140, and the core insulation layer 142 of the plurality of channel structures CH1, CH2, and CH3 have an integral structure. The present invention, however, is not limited thereto. In an embodiment, the gate dielectric layer 150, the channel layer 140, and the core insulation layer 142 of the plurality of channel structures CH1, CH2, and CH3 may be separately disposed and electrically connected with each other. A separate channel pad may be additionally provided at the connection portion of the plurality of channel structures CH1, CH2, and CH3. The form of the plurality of channel structures CH1, CH2, and CH3, however, is not limited thereto.

In an embodiment, the separation structure 146 may penetrate the gate stacking structure 120. The separation structure 146 may extend in a direction (e.g., the third direction (the Z direction)) intersecting (e.g., vertical) the first substrate 100. The separation structure may separate the gate stacking structure 120 into multiple partitions. In an embodiment, the separation structure 146 has an inclined side surface, and the width of the separation structure 146 gradually decreases toward the first substrate 100 when viewed in a cross-section view. In an embodiment, the separation structure 146 may have a high aspect ratio. The present invention, however, is not limited thereto. The side surface of the separation structure 146 may be vertical to the first substrate 100 or may have a bent portion at the connection portion of the plurality of gate stacking structures 120a, 120b, and 120c.

In an embodiment, the gate stacking structure 120 may further include an upper separation region positioned adjacent to the peri structure PERI. When viewed in a plan view, the separation structure 146 and/or the upper separation region extends in the first direction (the X direction) and may be spaced apart from each other with a predetermined interval in the second direction (the Y direction) intersecting the first direction. A plurality of separation structures 146 and/or upper separation regions may be provided. The present invention, however, is not limited thereto.

The separation structure 146 or the upper separation region may be filled with various insulating materials. For example, the separation structure 146 or the upper separation region may include or may be formed of an insulating material such as silicon oxide, silicon nitride, and silicon oxynitride. In an embodiment, the separation structure 146 may further include a semiconductor material or a metallic material. For example, the separation structure 146 may include a spacer layer including an insulating material, and a portion disposed on the spacer layer and including a semiconductor material, or a metallic material. The present invention, however, is not limited thereto. In an embodiment, the structure, shape, material, etc. of the separation structure 146 or upper separation region may be variously modified.

The cell structure CELL may include a cell wire part 180 to connect the gate stacking structure 120 and/or the channel structure CH provided on the cell array region CAR to the peri structure PERI or the external circuit.

In an embodiment, the cell wire part 180 may include conductive members which electrically connect the gate electrodes 130 and the channel structures CH to the peri structure PERI or the external circuit. For example, the cell wire part 180 may include a bit line BL, a gate contact 184, an input/output pad IO_PAD, an input/output contact 188, and a contact via 180a. According to an embodiment, a connection wire 190 connected to the bit line BL, the gate contact 184, and/or the input/output contact 188 may be further included.

In an embodiment, the bit line BL may be positioned on the bottom surface of the cell insulation layer 132 of the gate stacking structure 120 positioned on the cell array region CAR. The bit line BL may extend in a direction crossing the direction in which the gate electrode 130 extends. The bit line BL may be electrically connected to the channel structure CH (e.g., a channel pad 144) through the contact via 180a.

On the extending region EXT, a member for connecting the gate electrode 130 and the peri structure PERI with each other may be provided.

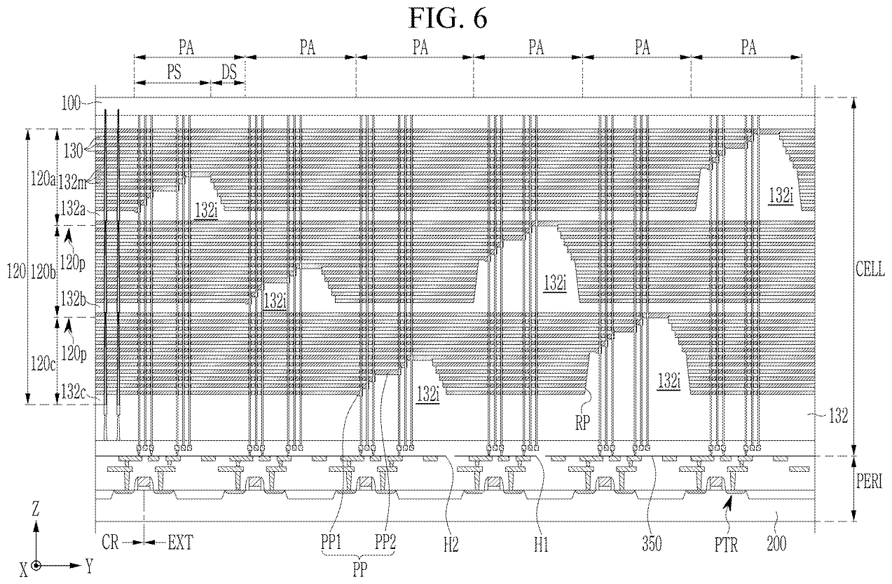

In an embodiment, a gate contact 184 may be provided on the extending region EXT. The gate contact 184 may extend in the third direction (the Z direction) on the extending region EXT and penetrate the cell insulation layer 132 and the mold structure MS. The gate contact 184 may be connected to any one of the plurality of gate electrodes 130 stacked in a stepped shape on the extending region EXT. For example, the gate contact 184 may be in contact with the sidewall of the connection gate electrode 130c including the pad portion PP. The pad portion PP of the connection gate electrode 130c may be in contact with the pad insulating part 132i. On better understanding and ease of description, eight gate contacts 184 are shown. The present invention, however, is not limited thereto. The connection structure of the gate contact 184 and the gate electrode 130 is described in detail with reference to FIG. 6.

In an embodiment, the upper surface of the gate contact 184 may be positioned within the insulation pattern 102. For example, the upper surface of the gate contact 184 may be provided between the front and rear surfaces of the insulation pattern 102. The gate contact 184 may non-overlap the common source plate 101 in the third direction (the Z direction). The gate contact 184 may not completely penetrate the first substrate 100. The gate contact 184 may include or may be formed of a conducting material. The gate contact 184 may include or may be formed of, for example, metal such as copper (Cu), tungsten (W), cobalt (Co), and nickel (Ni), but the type of metal is not limited thereto.

An insulation ring 184i may be provided within the gate stacking structure 120. The insulation ring 184i may be interposed between the gate contact 184 and each plurality of gate electrodes 130. The insulation ring 184i may electrically separate other gate electrodes except for the gate electrode 130 including the pad portion PP from the gate contact 184. For example, the insulation ring 184i may prevent the gate electrodes other than the connection gate electrode 130c connected to the gate contact 184 from being in contact with the gate contact 184. For example, the insulation ring 184i may be an annular structure surrounding the gate contact 184.

The insulation ring 184i may include or may be formed of an insulating material. The insulation ring 184i may include or may be formed of, for example, an oxide-based insulating material. For example, the insulation ring 184i may include or may be formed of silicon oxide, but it is not limited thereto.

In an embodiment, the gate contact 184 may be electrically connected to one of the plurality of gate electrodes 130 through the connection gate electrode 130c and may be insulated from the other gate electrodes 130 by the insulation pattern 102. The gate contact 184 may be positioned between the gate electrode 130 and the connection wire 190 and may connect the gate electrode 130 and the connection wire 190 with each other.

A source contact 186 may be provided on the pad region THR. The source contact 186 may include or may be formed of a conductive material such as metal, a metal compound, and polysilicon doped with impurities, and may be electrically connected to the common source plate 101. The source contact 186 may be electrically connected to the bit line BL through a connection wire 190. The connection wire 190 may include or may be formed of a conductive material. The connection wire 190 may include or may be formed of, for example, tungsten (W) or copper (Cu), but it is not limited thereto.

In an embodiment, the upper surface of the source contact 186 may be provided between the front and back surfaces of the first substrate 100. The source contact 186 may overlap the common source plate 101 in the third direction (the Z direction). The source contact 186 may non-overlap the insulation pattern 102 in the third direction (the Z direction). For example, when viewed in a plan view, the source contact 186 may be spaced apart from the insulation pattern 102. The source contact 186 does not completely penetrate the common source plate 101.

The input/output contact 188 may pass through the cell insulation layer 132 to be connected to the input/output pad IO_PAD to be described later. The input/output contact 188 may be provided on the pad region THR. In an embodiment, the common source plate 101 may not be positioned in a region where the input/output contact 188 is positioned. An insulation pattern 102 may be positioned in a region where the input/output contact 188 is disposed. The input/output contact 188 may overlap the insulation pattern 102 in the third direction (the Z direction).

The input/output contact 188 may not overlap the plurality of gate electrodes 130 in the third direction (the Z direction). When viewed in a plan view, the input/output contact 188 may be spaced apart from the plurality of gate electrodes 130. The input/output contact 188 may be electrically connected to the bit line BL through a connection wire 190.

In an embodiment, the second barrier structure US may be positioned on the surface facing the peri structure PERI and may be disposed on the cell wire part 180. The second barrier structure US may be positioned on the bottom surface of the bit line BL. The second barrier structure US may be connected to a first barrier structure LS of the peri structure PERI. The description of the first barrier structure LS will be described later.

The second barrier structure US may include a plurality of upper barrier layers UB1 and UB2 and a plurality of upper interlayer insulating layers 301, 302, 303, and 304 sequentially stacked in the third direction (the Z direction) on the bottom surface of the bit line BL.

The plurality of upper barrier layers UB1 and UB2 may include a first upper barrier layer UB1 and a second upper barrier layer UB2.

The first upper barrier layer UB1 may be positioned on the bottom surface of the bit line BL to be in contact with the bit line BL. The second upper barrier layer UB2 may be positioned on the first upper barrier layer UB1 to be spaced apart from the first upper barrier layer UB1 in the third direction (the Z direction) away from the first substrate 100.

In an embodiment, the plurality of upper barrier layers UB1 and UB2 may include or may be formed of silicon nitride. The present invention, however, is not limited thereto, and each of the plurality of upper barrier layers UB1 and UB2 may include or may be formed of at least one of silicon carbonitride and silicon oxynitride. The plurality of upper barrier layers UB1 and UB2 may include or may be formed of the same material as the plurality of lower barrier layers LB1, LB2, and LB3. In the process of manufacturing the upper wires UM1 and UM2 and the upper contact vias UC1 and UC2, the plurality of upper barrier layers UB1 and UB2 may serve as a diffusion barrier to prevent a material forming the upper wires UM1 and UM2 and the upper contact vias UC1 and UC2 from being diffused to the surroundings.

The number of upper barrier layers and the number of upper interlayer insulating layers are not limited thereto. In an embodiment, the arrangement structure of the upper barrier layers and the number of upper barrier layers may be formed in various ways.

In the plurality of upper interlayer insulating layers 301, 302, 303, and 304, the upper wires UM1 and UM2 and the upper contact via UC1 and UC2 may be positioned.

The first and second upper interlayer insulating layers 301 and 302 may be sequentially stacked on the bottom surface of the first upper barrier layer UB1, and the cell wire part 180 may be connected to the first upper wire UM1 through the first upper contact via UC1 passing through the first upper barrier layer UB1.

The third upper interlayer insulating layer 303 may be stacked on the bottom surface of the second upper barrier layer UB2, and the fourth upper interlayer insulating layer 304 may be positioned between the third upper interlayer insulating layer 303 and the junction insulation layer 350.

The second upper wire UM2 may be connected to the first upper wire UM1 through the second upper contact via UC2 penetrating the second upper barrier layer UB2.

The semiconductor device according to an embodiment may further include a first upper insulation layer 103, a second upper insulation layer 104, an input/output pad IO_PAD, a cell pad C_PAD, an input/output via IO_VA, and a cell via C_VA.

The first upper insulation layer 103 may be provided on the rear surface of the first substrate 100. The first upper insulation layer 103 may include or may be formed of an oxide-based insulating material including proton (H⁺). The first upper insulation layer 103 may include or may be formed of an insulating material having a relatively high proton (H⁺) supply capability. For example, the first upper insulation layer 103 may include or may be formed of a high density plasma (HDP) oxide. The first upper insulation layer 103 may be referred to as ‘hydrogen passivation layer’ or ‘hydrogen supply layer’. The present invention, however, is not limited thereto, and the first upper insulation layer 103. For example, the first upper insulation layer 103 may include or may be formed of flowable oxide (FOX), tonen silazen (TOSZ), undoped silica glass (USG), borosilica glass (BSG), phosphor silica glass (PSG), borophosphosilica glass (BPSG), plasma enhanced tetra-ethyl ortho silicate (PE-TEOS), fluoride silicate glass (FSG), plasma enhanced oxide (PEOX), or a combination thereof, each of which includes proton (H⁺).

The second upper insulation layer 104 may be provided on the first upper insulation layer 103. The second upper insulation layer 104 may include or may be formed of a material having etch selectivity against the first upper insulation layer 103. The second upper insulation layer 104 may include or may be formed of, for example, silicon nitride (SiN). The present invention, however, is not limited thereto.

The input/output pad IO_PAD may be provided on the second upper insulation layer 104 which is disposed on the pad region THR. The input/output pad IO_PAD may be connected to the input/output via IO_VA and the input/output contact 188. The input/output pad IO_PAD may be electrically connected to the peri structure PERI through the input/output contact 188 and the input/output via IO_VA. The input/output pad IO_PAD may electrically connect an external device and the semiconductor device with each other. The input/output pad IO_PAD may include or may be formed of a conductive material. In an embodiment, the input/output pad IO_PAD may include or may be formed of aluminum (Al). The present invention, however, is not limited thereto.

The cell pad C_PAD may be provided on the second upper insulation layer 104 of the cell array region CAR. The cell pad C_PAD may be connected to the cell via C_VA and the common source plate 101. The cell pad C_PAD may be electrically connected to the common source plate 101 through the cell via C_VA. The cell pad C_PAD may include or may be formed of a conductive material. For example, the cell pad C_PAD may include or may be formed of aluminum (Al). The present invention, however, is not limited thereto.

The input/output via IO_VA may pass through the second upper insulation layer 104 and the first upper insulation layer 103. The input/output via IO_VA may be provided on the pad region THR. The input/output via IO_VA may be disposed on the pad region THR and may overlap the insulation pattern 102 in the third direction (the Z direction). The input/output via IO_VA may not completely penetrate the first substrate 100. The input/output via IO_VA may electrically connect the input/output contact 188 and the input/output pad IO_PAD with each other. In an embodiment, the input/output via IO_VA may be a diffusion passage of proton (H⁺). For example, protons (H⁺) supplied from the first upper insulation layer 103 may be diffused in a direction away from the first upper insulation layer 103 through the input/output via IO_VA. For example, hydrogen ions (H⁺) may be diffused in the third direction (the Z direction).

The cell via C_VA may pass through the second upper insulation layer 104 and the first upper insulation layer 103. The cell via C_VA may be provided on the common source plate 101 of the cell array region CAR. The cell via C_VA may overlap the common source plate 101 in the third direction (the Z direction). The cell via C_VA may electrically connect the cell pad C_PAD and the common source plate 101 with each other. In an embodiment, the cell via C_VA may be a diffusion passage of proton(H⁺). For example, proton (H⁺) may be diffused through the cell via C_VA.

In an embodiment, proton (H⁺) included in the first upper insulation layer 103 may be diffused into the circuit element PTR of the peri structure PERI through the cell via C_VA and/or the input/output via IO_VA. In the process of performing a heat treatment process (e.g., an alloy process) on the semiconductor device according to an embodiment, proton(H⁺) included in the first upper insulation layer 103 may be diffused through the diffusion passage. For example, proton (H⁺) may be diffused to the common source plate 101 through the cell via C_VA, and may be diffused to the second barrier structure US through the gate contact 184 connected to the common source plate 101 and/or the channel structure CH. Proton (H⁺) may be diffused to the second barrier structure US through the input/output via IO_VA and the input/output contact 188.

Proton (H⁺) diffused to the second barrier structure US may be diffused to the circuit element PTR through the first barrier structure LS of the peri structure PERI.

As described above, when the circuit element PTR is formed of a transistor, the circuit element may include a gate electrode and a channel region, and a gate insulating layer between the channel region and the gate electrode. The performance of the circuit element PTR may be determined according to the concentration of protons (H⁺) which are diffused in the gate insulating layer of the circuit element PTR. Therefore, in an embodiment, when proton (H⁺) is diffused in the gate insulating layer of the circuit element PTR positioned in the peri structure PERI, the performance of the circuit element PTR may be improved. Therefore, when a constant concentration of proton (H⁺) is diffused in the circuit element PTR positioned in the peri structure PERI, there is no difference in the performance between various circuit elements PTR, and a similar characteristic may be obtained. In an embodiment, a uniform distribution of protons (H⁺) among the various circuit elements PTR may prevent difference in the performance of the various circuit elements PTR, thereby securing the uniform performance among the various circuit elements PTR.

In FIG. 2, when viewed in a cross-section view, the gate contact 184 has a slanted side so that the width of the gate contact 184 narrows as it approaches the first substrate 100, and the input/output contact 188 has a slanted side such that the width of the input/output contact 188 increases as it approaches the first substrate 100. The present invention, however, is not limited thereto. In an embodiment, the gate contact 184 and/or the input/output contact 188 may have the vertical side extending in a particular direction relative to the rear or front surface of the first substrate 100. FIG. 2 illustrates that the gate contact 184 has the bent portion at the boundary of the plurality of gate stacking structures 120a, 120b, and 120c. The embodiment, however, is not limited thereto. In an embodiment, the gate contact 184 does not have the bent portion at the boundary of the plurality of gate stacking structures 120a, 120b, and 120c. Numerous other variations are possible.

Hereinafter, the peri structure PERI is described.

The peri structure PERI may include a second substrate 200, a circuit element PTR positioned on the second substrate 200, a first barrier structure LS positioned on the second substrate 200, lower contact vias LC1, LC2, and LC3 penetrating at least a portion of the first barrier structure LS, and lower wires LM1, LM2, and LM3.

In an embodiment, one surface of the peri structure PERI adjacent to the cell structure CELL is a junction surface with the cell structure CELL, and may be composed of a part of the second junction structure 290 and the junction insulation layer 350. One surface of the cell structure CELL adjacent to the peri structure PERI is a junction surface with the peri structure PERI, and may be composed of a part of the first junction structure 280 and the junction insulation layer 350 positioned therearound. The second junction structure 290 may be electrically connected to the circuit element PTR through the lower wires LM1, LM2, and LM3. The first junction structure 280 may be electrically connected to the cell wire part 180 through the upper wires UM1 and UM2.

One surface of the cell structure CELL and one surface of the peri structure PERI may be joined by a hybrid junction. For example, the second junction structure 290 of the peri structure PERI and the first junction structure 280 of the cell structure CELL are directly contacted and joined with each other, thereby forming a metal junction. A part of the junction insulation layer 350 of the peri structure PERI and a part of the junction insulation layer 350 of the cell structure CELL may be joined with each other, thereby forming the junction insulation layer 350.

For example, the second junction structure 290 and/or the first junction structure 280 may be made of copper, aluminum, tungsten, nickel, gold, tin, manganese, cobalt, titanium, tantalum, ruthenium, or an alloy thereof. For example, the second junction structure 290 and/or the first junction structure 280 includes at least copper in the junction surface, so that the metal junction of the peri structure PERI and the cell structure CELL may correspond to a copper-to-copper junction. The present invention, however, is not limited to the copper-to-copper junction as the second junction structure 290 and the first junction structure 280.

The second junction structure 290 of the peri structure PERI and the first junction structure 280 of the cell structure CELL are joined with each other, thereby providing the electrical connection path between the peri structure PERI and the cell structure CELL. For example, by the upper wires UM1 and UM2 and the lower wires LM1, LM2, and LM3, the bit line BL and/or the gate electrode 130 connected to the channel structure CH may be electrically connected to the circuit element PTR of the peri structure PERI.

The second substrate 200 may include a front surface and a rear surface opposite to each other. The front surface of the second substrate 200 may face the cell structure CELL. The rear surface of the second substrate 200 may face the cell structure CELL.

The second substrate 200 may be a semiconductor substrate including a semiconductor material. For example, the second substrate 200 may be a semiconductor substrate made of a semiconductor material or may be a semiconductor substrate on which a semiconductor layer is formed on a base substrate. For example, the second substrate 200 may be configured of single crystal or polysilicon, epitaxial silicon, germanium, or silicon-germanium, silicon-on-insulator (SOI), or germanium-on-insulator (GOI).

The circuit element PTR may be positioned on the second substrate 200. The circuit element PTR may include various circuit elements that control the operation of the memory cell structure provided in the cell structure CELL. For example, the circuit element PTR may constitute a peripheral circuit structure such as a decoder circuit (a reference numeral 1110 in FIG. 25), a page buffer (a reference numeral 1120 in FIG. 25), and a logic circuit (a reference numeral 1130 in FIG. 25). The circuit element PTR may include, for example, a transistor, but it is not limited thereto. For example, the circuit element PTR may include not only active elements such as transistors, but also passive elements such as capacitors, resistors, and inductors.

The first barrier structure LS may be positioned on the second substrate 200. For example, the first barrier structure LS may be positioned on the front surface of the second substrate 200. For example, the first barrier structure LS may be positioned between the cell structure CELL and the second substrate 200.

Referring to FIG. 5, the first barrier structure LS may include a plurality of lower barrier layers LB1, LB2, and LB3 and a plurality of lower interlayer insulating layers 401, 402, 403, 404, 405, and 406 sequentially stacked on a second substrate 200 in a third direction (a Z direction). The plurality of lower barrier layers LB1, LB2, and LB3 and the plurality of lower interlayer insulating layers 401, 402, 403, 404, 405, and 406 may be alternately stacked on the second substrate 200.

The plurality of lower barrier layers LB1, LB2, and LB3 may include a first lower barrier layer LB1, a second lower barrier layer LB2, and a third lower barrier layer LB3.

The first lower barrier layer LB1 may be spaced apart from the second substrate 200. For example, the first lower barrier layer LB1 may be positioned on an inter-wire insulation layer 240 positioned on the second substrate 200. The second lower barrier layer LB2 may be spaced apart from the first lower barrier layer LB1 in the third direction (the Z direction) away from the second substrate 200. The third lower barrier layer LB3 may be spaced apart from the second lower barrier layer LB2 in the third direction (the Z direction) away from the second substrate 200. The second lower barrier layer LB2 may be positioned between the first and third lower barrier layers LB1 and LB3.

In an embodiment, the plurality of lower barrier layers LB1, LB2, and LB3 may include or may be formed of silicon nitride. The present invention, however, is not limited thereto. In an embodiment, each of the plurality of lower barrier layers LB1, LB2, and LB3 may include or may be formed of at least one of silicon carbonitride and silicon oxynitride. In the process of manufacturing the lower wires LM1, LM2, and LM3 and the lower contact vias LC1, LC2, and LC3, the plurality of lower barrier layers LB1, LB2, and LB3 may serve as a diffusion barrier to prevent material forming the lower wires LM1, LM2, and LM3 and the lower contact vias LC1, LC2, and LC3 from being diffused to the surroundings.

Within the plurality of lower interlayer insulating layers 401, 402, 403, 404, 405, and 406, the lower wires LM1, LM2, and LM3 and the lower contact vias LC1, LC2, and LC3 may be positioned.

The first lower interlayer insulating layer 401 may be stacked on the first lower barrier layer LB1, and the second lower interlayer insulating layer 402 may be stacked on the first lower interlayer insulating layer 401.

The first lower wire LM1 may be positioned within the second lower interlayer insulating layer 402. The upper surface of the first lower wire LM1 may be in contact with the bottom surface of the second lower barrier layer LB2. For example, the upper surface of the first lower wire LM1 may be positioned at a level substantially equivalent to the upper surface of the second lower interlayer insulating layer 402. The first lower wire LM1 may be connected to the circuit element wire PTM through a first lower contact via LC1 penetrating the first lower barrier layer LB1. Accordingly, the first lower wire LM1 may be connected to the source/drain region of the peripheral circuit element PTR. The first lower wire LM1 may be formed integrally with the first lower contact via LC1 without a boundary therebetween. The present invention, however, is not limited thereto.

A third lower interlayer insulating layer 403 may be stacked on the second lower barrier layer LB2, and a fourth lower interlayer insulating layer 404 may be stacked on the third lower interlayer insulating layer 403.

The second lower wire LM2 may be positioned within the fourth lower interlayer insulating layer 404. The upper surface of the second lower wire LM2 may be in contact with the bottom surface of the third lower barrier layer LB3. For example, the upper surface of the second lower wire LM2 may be positioned at a level substantially equivalent to the upper surface of the fourth lower interlayer insulating layer 404. The second lower wire LM2 may be connected to the first lower wire LM1 through a second lower contact via LC2 penetrating the second lower barrier layer LB2. The second lower wire LM2 may be formed integrally with the second lower contact via LC2 without a boundary therebetween, but it is not limited thereto.

A fifth lower interlayer insulating layer 405 may be stacked on the third lower barrier layer LB3, and a sixth lower interlayer insulating layer 406 may be stacked on the fifth lower interlayer insulating layer 405. A junction insulation layer 350 may be stacked on the sixth lower interlayer insulating layer 406.

The third lower wire LM3 may be positioned within the sixth lower interlayer insulating layer 406 and junction insulation layer 350. The third lower wire LM3 may be connected to the second lower wire LM2 through a third lower contact via LC3 penetrating the third lower barrier layer LB3. The third lower wire LM3 may be formed integrally with the third lower contact via LC3 without a boundary therebetween, but it is not limited thereto.

The upper surfaces of the lower wires LM1, LM2, and LM3 may be in contact with the plurality of lower barrier layers LB1, LB2, and LB3. The bottom surface and side surfaces of the lower wires LM1, LM2, and LM3 may be surrounded by the plurality of lower interlayer insulating layers 401, 402, 403, 404, 405, and 406. For example, the side surface of the first lower wire LM1 may be surrounded by the second lower interlayer insulating layer 402. The bottom surface of the first lower wire LM1 may be in contact with the first lower interlayer insulating layer 401. The side surface of the second lower wire LM2 may be surrounded by the fourth lower interlayer insulating layer 404. The bottom surface of the second lower wire LM2 may be in contact with the third lower interlayer insulating layer 403.

In FIG. 2, the number of plurality of lower barrier layers LB1, LB2, and LB3 is three. The present invention, however, is not limited thereto. For example, four lower barrier layers may be stacked on the second substrate 200. In an embodiment, two lower barrier layers may be laminated on the second substrate 200.

The plurality of lower interlayer insulating layers 401, 402, 403, 404, 405, and 406 may include or may be formed of an insulating material. For example, the plurality of lower interlayer insulating layers 401, 402, 403, 404, 405, and 406 may include or may be formed of silicon oxide, silicon nitride, silicon oxynitride, a low dielectric constant material having a smaller dielectric constant than silicon oxide, or a combination thereof.

The lower wires LM1, LM2, and LM3 and the lower contact vias LC1, LC2, and LC3 may include or may be formed of a conductive material. For example, a plurality of lower wires LM1, LM2, and LM3 and a plurality of lower contact vias LC1, LC2, and LC3 may include or may be formed of copper (Cu). The present invention, however, is not limited thereto. In an embodiment, the plurality of lower wires LM1, LM2, and LM3 and the plurality of lower contact vias LC1, LC2, and LC3 may include or may be formed of tungsten (W).

In an embodiment, the hydrogen permeability of the plurality of lower interlayer insulating layers 401, 402, 403, 404, 405, and 406, lower wires LM1, LM2, and LM3, and the lower contact vias LC1, LC2, and LC3 may be greater than the hydrogen permeability of the plurality of lower barrier layers LB1, LB2, and LB3. For example, as described above, when the plurality of lower barrier layers LB1, LB2, and LB3 include or are formed of silicon nitride, the hydrogen permeability of the plurality of lower barrier layers LB1, LB2, and LB3 may be smaller than the hydrogen permeability of at least one among of the plurality of lower interlayer insulating layers 401, 402, 403, 404, 405, and 406, the lower wires LM1, LM2, and LM3, and the lower contact vias LC1, LC2, and LC3. The hydrogen permeability of a layer may mean a degree of proton (H⁺) supplied from the hydrogen supply layer (e.g., the first upper insulation layer 103) penetrating and diffusing through the layer.

Accordingly, protons (H⁺) supplied from the first upper insulation layer 103 may be diffused to the circuit element PTR through the first barrier structure LS. The hydrogen permeability of the plurality of lower barrier layers LB1, LB2, and LB3 is relatively low, and the protons (H⁺) may rarely penetrate the plurality of lower barrier layers LB1, LB2, and LB3. In an embodiment, the plurality of lower barrier layers LB1, LB2, and LB3 may include a diffusion path of the protons (H⁺) using holes formed therein as described below.

In an embodiment, the plurality of lower barrier layers LB1, LB2, and LB3 may include a plurality of first via holes H1 and a plurality of second via holes H2. For example, the plurality of first via holes H1 may be formed in the plurality of lower barrier layers LB1, LB2, and LB3, and the plurality of second via holes H2 may be formed in the plurality of lower barrier layers LB1, LB2, and LB3.

The plurality of first via holes H1 may be positioned on the cell region CR and the pad region THR. For example, at least one of the plurality of first via holes H1 may be positioned on the cell array region CAR, at least one of the plurality of first via holes H1 may be positioned on the extending region EXT, and at least one of the plurality of first via holes H1 may be positioned on the pad region THR.

The plurality of first via holes H1 may pass through at least a part of the first barrier structure LS. At least one of the plurality of first via holes H1 may pass through any one of the plurality of lower barrier layers LB1, LB2, and LB3. For example, as shown in FIG. 5, on the cell region CR and the pad region THR, at least one of the plurality of first via holes H1 may pass through the first lower barrier layer LB1, and at least one of the plurality of first via holes H1 may pass through the second lower barrier layer LB2. The present invention, however, is not limited thereto. In an embodiment, at least one of the plurality of first via holes H1 may pass through each of the plurality of lower barrier layers LB1, LB2, and LB3.

Within the plurality of first via holes H1, the lower contact vias LC1, LC2, and LC3 may be positioned. For example, as shown in FIG. 5, on the cell region CR and the pad region THR, the first lower contact vias LC1, LC2, and LC3 may be positioned within the plurality of first via holes H1 of the first lower barrier layer LB1. On the cell region CR and pad region THR, the second lower contact vias LC1, LC2, and LC3 may be positioned within the plurality of first via holes H1 of the second lower barrier layer LB2. For example, the lower contact vias LC1, LC2, and LC3 pass through the plurality of lower barrier layers LB1, LB2, and LB3 via the plurality of first via holes H1.

In an embodiment, the plurality of first via holes H1 may overlap the lower wires LM1, LM2, and LM3 or the circuit element wire PTM in the third direction (the Z direction). For example, the plurality of first via holes H1 of the first lower barrier layer LB1 may overlap the circuit element wire PTM in the third direction (the Z direction). The plurality of first via holes H1 of the second lower barrier layer LB2 may overlap the first lower wire LM1 in the third direction (the Z direction). The lower contact vias LC1, LC2, and LC3 positioned within the plurality of first via holes H1 may be connected to the lower wires LM1, LM2, and LM3 positioned on the bottom surface of the plurality of first via holes H1.

In an embodiment, the ratio of the sum of the areas of the plurality of first via holes H1 on the pad region THR for the entire area of the pad region THR may be greater than the ratio of the sum of the areas of the plurality of first via holes H1 on the cell region CR for the entire area of the cell region CR. The sum of the areas of the plurality of first via holes H1 per unit area on the pad region THR may be greater than the sum of the areas of the plurality of first vias hole H1 per unit area on the cell region CR. For example, the plurality of first via holes H1 may be distributed in both the cell region CR and the pad region THR. The sum of the areas of at least one of the plurality of first via holes H1 per unit area on the pad region THR may be greater than the sum of the areas of at least one of the plurality of first via holes H1 per unit area on the cell region CR.

Here, that the sum of the areas of the plurality of first via hole H1 per unit area is large may mean that the number of plurality of first vias hole H1 per unit area is large or the average diameter of the plurality of first via holes H1 is large. In an embodiment, the number of plurality of first via holes H1 per unit area on the pad region THR may be greater than the number of plurality of first via holes H1 per unit area on the cell region CR. In an embodiment, the average diameter of the plurality of first via holes H1 on the pad region THR may be greater than the average diameter of the plurality of first via holes H1 on the cell region CR.

The ratio of the area of the lower contact vias LC1, LC2, and LC3 on the pad region THR for the unit area of the pad region THR may be greater than the ratio of the area of lower contact vias LC1, LC2, and LC3 on the cell region CR for the unit area of the cell region CR.

Hereinafter, for better understanding and ease of description, the ratio of the sum of the areas of the plurality of first via holes H1 per unit area of each region will be referred to as ‘a density’. The density of the plurality of first via holes H1 on the pad region THR may be a ratio of the sum of the areas of plurality of the first via holes H1 on the pad region THR for the unit area of the pad region THR. Also, the density of the plurality of first via holes H1 in cell region CR may be a ratio of the sum of the areas of the plurality of first via holes H1 on the cell region CR for the unit area of the cell region CR. In an embodiment, the density of the plurality of first via holes H1 on the pad region THR may be greater than the density of the plurality of first via holes H1 on the cell region CR.

In an embodiment, in at least one among the plurality of lower barrier layers LB1, LB2, and LB3, the density of the plurality of first via holes H1 on the pad region THR may be greater than the density of plurality of first via holes H1 on the cell region CR. For example, as shown in FIG. 5, the number of the plurality of first via holes H1 per unit area of the first lower barrier layer LB1 on the pad region THR may be greater than the number of the plurality of first via holes H1 per unit area of the first lower barrier layer LB1 on the cell region CR. Accordingly, the density of the plurality of first via holes H1 of the first lower barrier layer LB1 on the pad region THR may be greater than the density of the plurality of first via holes H1 of the first lower barrier layer LB1 on the cell region CR.

The present invention is not limited thereto. In an embodiment, the average diameter of the plurality of first via holes H1 on the pad region THR may be greater than the average diameter of the plurality of first via holes H1 on the cell region CR. The density of the plurality of first via holes H1 of the first lower barrier layer LB1 on the pad region THR may be greater than the density of the plurality of first via holes H1 of the first lower barrier layer LB1 on the cell region CR.

In an embodiment, the plurality of first via holes H1 may be positioned in the first lower barrier layer LB1 and the second lower barrier layer LB2, and the plurality of first via holes H1 may be positioned in the third lower barrier layer LB3. The present invention, however, is not limited thereto. In an embodiment, each of the plurality of lower barrier layers LB1, LB2, and LB3 may include at least one first via hole H1.

In an embodiment, the plurality of second via holes H2 may be positioned on the cell region CR.

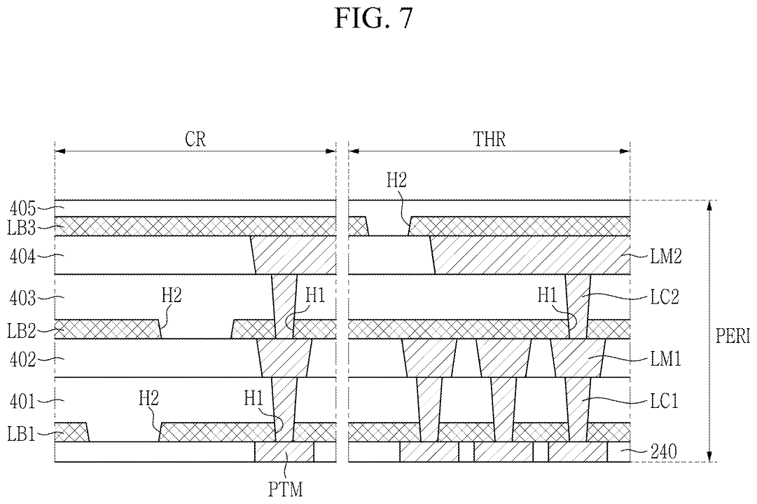

The plurality of second via holes H2 may not be positioned on the pad region THR. The present invention, however, is not limited thereto. The description of this is described with reference to FIG. 7 later.

The plurality of second via holes H2 may penetrate at least part of the first barrier structure LS. The plurality of second via holes H2 may pass through any one of the plurality of lower barrier layers LB1, LB2, and LB3. For example, as shown in FIG. 5, on the cell region CR, the plurality of second via holes H2 may pass through the first lower barrier layer LB1 and the second lower barrier layer LB2. The present invention, however, is not limited thereto. In an embodiment, at least one of the plurality of second via holes H2 may pass through each of the plurality of lower barrier layers LB1, LB2, and LB3.

The plurality of lower interlayer insulating layers 401, 402, 403, 404, 405, and 406 may be positioned within the plurality of second via holes H2. The plurality of second via holes H2 may non-overlap the lower wires LM1, LM2, and LM3 in the third direction (the Z direction). For example, as shown in FIG. 5, on the cell region CR, the first lower interlayer insulating layer 401 may be positioned within the plurality of second via holes H2 of the first lower barrier layer LB1. The bottom surface of the plurality of second via holes H2 of the first lower barrier layer LB1 may be defined by the inter-wire insulation layer 240. On the cell region CR, the third lower interlayer insulating layer 403 may be positioned within the plurality of second via holes H2 of the second lower barrier layer LB2. The bottom surface of the plurality of second via holes H2 of the second lower barrier layer LB2 may be defined by the second lower interlayer insulating layer 402. In an embodiment, the plurality of second via holes H2 may be dummy via holes for transferring protons (H⁺) to the circuit elements of the peri structure PERI. In an embodiment, the plurality of first via holes H1 may be via holes for electrically connecting the circuit element of the peri structure PERI and the lower wires LM1, LM2, and LM3. In an embodiment, the density of the plurality of first via holes H1 on the pad region THR may be substantially equivalent to the density of the plurality of first via holes H1 and the plurality of second via holes H2 on the cell region CR. For example, the sum of the areas of the plurality of first via holes H1 per unit area on the pad region THR may be substantially equivalent to the sum of the areas of the plurality of first via holes H1 and the areas of the plurality of second via holes H2 per unit area on the cell region CR.

In an embodiment, in at least one of the plurality of lower barrier layers LB1, LB2, and LB3, the density of the plurality of first via holes H1 on the pad region THR may be substantially equivalent to the density of the plurality of first via holes H1 and the plurality of second via holes H2 on the cell region CR. For example, as shown in FIG. 5, the area of the plurality of first via holes H1 per unit area of the first lower barrier layer LB1 on the pad region THR may be substantially equivalent to the sum of the area of the plurality of first via hole H1 and the area of the plurality of second via hole H2 per unit area of the first lower barrier layer LB1 on the cell region CR.

In an embodiment, in each of the plurality of lower barrier layers LB1, LB2, and LB3, the density of the plurality of first via holes H1 on the pad region THR may be substantially equivalent to the density of the plurality of first via holes H1 and the plurality of second via holes H2 on the cell region CR. For example, the sum of the areas of the plurality of first via holes H1 of the first lower barrier layer LB1 per unit area on the pad region THR may be substantially equivalent to the sum of the areas of the plurality of first via holes H1 and the area of the plurality of second via holes H2 of the first lower barrier layer LB1 per unit area on the cell region CR. The sum of the areas of the plurality of first via hole H1 per unit area of the second lower barrier layer LB2 on the pad region THR may be substantially equivalent to the sum of the areas of the plurality of first via holes H1 and the areas of the plurality of second via holes H2 per unit area of the second lower barrier layer LB2 on the cell region CR.

In an embodiment, the density of the plurality of second via holes H2 may increase as it is distant away from the pad region THR. The present invention, however, is not limited thereto.

In an embodiment, the junction insulation layer 350 does not include the plurality of second via holes H2. The present invention, however, is not limited thereto. For example, on the cell region CR, the junction insulation layer 350 may include the plurality of second via holes H2. The plurality of second via hole H2 may be spaced apart from the lower wires LM1, LM2, and LM3 and the circuit element wire PTM. For example, the plurality of second via holes H2 may not overlap the lower wires LM1, LM2, and LM3 or the circuit element wire PTM in the third direction (the Z direction). For example, the plurality of second via holes H2 of the first lower barrier layer LB1 may be spaced apart from the circuit element wire PTM in an elongation direction of the second substrate 200 along which the cell region CR and the pad region THR are arranged. The elongation direction may be parallel to the front or rear surface of the second substrate 200. The plurality of second via holes H2 of the second lower barrier layer LB2 may be spaced apart from the first lower wire LM1 in the elongation direction of the second substrate 200. For example, a separation distance D1 between the first lower wire LM1 and the plurality of second via holes H2 in the elongation direction of the second substrate 200 may be 100 nm or more. The separation distance D1 may correspond to a shortest distance between the first lower wire LM1 and one of the plurality of second via holes H2 adjacent thereto in the elongation direction. When the separation distance D1 is less than 100 nm, in the process of forming the lower wires LM1, LM2, and LM3, the material forming the lower wires LM1, LM2, and LM3 may be diffused through the plurality of second via hole H2, which may cause an electrical short circuit path.

In the process of performing a heat treatment (Alloy) process on the semiconductor device according to an embodiment, proton (H⁺) supplied from the first upper insulation layer 103 may be diffused to the circuit element PTR through the first barrier structure LS. The protons (H⁺) which are diffused into the gate insulating layer of the circuit element PTR may improve the performance of the circuit element PTR. Therefore, the gate insulation layer of the circuit element PTR in the peri structure PERI may have a constant concentration of protons (H⁺).

In the semiconductor device according to an embodiment, the hydrogen permeability of the plurality of lower barrier layers LB1, LB2, and LB3 may be less than the hydrogen permeability of the plurality of lower interlayer insulating layers 401, 402, 403, 404, 405, and 406, the lower wires LM1, LM2, and LM3, and the lower contact vias LC1, LC2, and LC3. Therefore, protons (H⁺) may be diffused through via holes penetrating the plurality of lower barrier layers LB1, LB2, and LB3. The density of the plurality of first via holes H1 on the pad region THR of the semiconductor device according to an embodiment may be greater than the density of the plurality of first via holes H1 on the cell region CR. On the pad region THR, the concentration of protons (H⁺) diffused to the circuit element PTR through the plurality of first via holes H1 may be greater than the concentration of protons (H⁺) diffused to the circuit element PTR through the plurality of first via holes H1 on the cell region CR.

The semiconductor device according to an embodiment may include the plurality of second via holes H2 on the cell region CR, and the density of the plurality of first via holes H1 on the pad region THR may be substantially equivalent to the density of the plurality of first via holes H1 and the plurality of second via holes H2 on the cell region CR. Accordingly, the concentration of protons (H⁺) diffused in the circuit element PTR positioned on the pad region THR may be substantially equivalent to the concentration of protons (H⁺) diffused in the circuit element PTR positioned on the cell region CR. Therefore, the circuit element PTR may exhibit the uniform performance, and the reliability of the semiconductor device may be improved.

In the following, the connection structure of the gate electrode 130 and the gate contact 184 will be described with reference to FIG. 2 to FIG. 6.

FIG. 6 is a partial cross-sectional view of a semiconductor device according to an embodiment.

Referring to FIG. 2 and FIG. 6, in an embodiment, a gate electrode 130 and an interlayer insulating layer 132m of a plurality of gate stacking structures 120a, 120b, and 120c may extend in a first direction (an X direction) and may be positioned on the extending region EXT. The extending region EXT of the first substrate 100 may include a plurality of pad connection regions PA on which the gate contact 184 and the gate electrode 130 are connected with each other.

The pad connection region PA may include a first region PS formed by a recessed portion RP from which the gate electrode 130 is removed and a second region DS. The recessed portion RP of each pad connection region PA may have a shape filled by the pad insulating part 132i.

In an embodiment, on the first region PS, a plurality of gate electrodes 130 may be sequentially removed during a time when the recessed portion RP is formed. On the first region PS, a plurality of gate electrodes 130 may have a stair shape. For example, on the first region PS, the length of the plurality of gate electrodes 130 may be sequentially shortened in a direction away from the cell array region CAR.

On the second region DS, the plurality of gate electrodes 130 may be sequentially removed during a time when the recessed portion RP is formed. As an embodiment, in the second region DS, the length of the plurality of gate electrodes 130 may be sequentially shortened while going downward in a direction toward the cell array region CAR. The stair shape of the plurality of gate electrodes 130 in the second region DS may have a steeper slope than the stair shape of the plurality of gate electrodes 130 on the first region PS, but an embodiment is not limited thereto.

In an embodiment, the recessed portion RP suffices to have a shape or a profile to sequentially expose the plurality of pad portions PP of the plurality of connection gate electrodes 130c in each pad connection region PA. The shape or profile of the recessed portion RP or the gate electrode 130 may be the same or similar on the first region PS and the second region DS of each pad connection region PA.

Accordingly, in each pad connection region PA, each of the plurality of gate contacts 184 may be electrically connected to a corresponding one of the pad portions PP of the plurality of connection gate electrodes 130c exposed through the recessed portion RP.

FIG. 6 illustrates that the first region PS and the second region DS are sequentially positioned in the direction apart from the cell array region CAR. However, this is only presented as an example, and an embodiment is not limited thereto.

Hereinafter, the semiconductor devices according to some embodiments are described with reference to FIG. 7 to FIG. 9.

FIG. 7 is a cross-sectional view showing a first barrier structure of a semiconductor device according to some embodiments.

The semiconductor device according to the embodiment as shown in FIG. 7 is the same as most of the semiconductor device according to the embodiment shown in FIG. 6 so that the description thereof is omitted and differences will be mainly described. The same reference numerals are used for the same constituent elements as the previous embodiment. In the present embodiment, the positioning of the plurality of second via holes H2 on the pad region THR is partially different from the previous embodiment, which will be described below.

Referring to FIG. 7, a peri structure PERI of a semiconductor device according to some embodiment may include a second substrate 200, a circuit element PTR positioned on the second substrate 200, a first barrier structure LS positioned on the second substrate 200, lower contact vias LC1, LC2, and LC3 penetrating at least part of the first barrier structure LS, and lower wires LM1, LM2, and LM3. The plurality of lower barrier layers LB1, LB2, and LB3 of the first barrier structure LS may include a plurality of first via holes H1 and a plurality of second via holes H2.

The plurality of second via holes H2 in the previous embodiment may be positioned on the cell region CR. The plurality of second via holes H2 may not be positioned on the pad region THR.

Referring to FIG. 7, the plurality of second via holes H2 of the present embodiment may be positioned on the cell region CR and the pad region THR.

On the pad region THR, the plurality of second via holes H2 may pass through at least part of the first barrier structure LS. On the pad region THR, the plurality of second via holes H2 may pass through any one of the plurality of lower barrier layers LB1, LB2, and LB3. For example, as shown in FIG. 5, on the pad region THR, the plurality of second via holes H2 may pass through the third lower barrier layer LB3. The present invention, however, is not limited thereto. In an embodiment, on the pad region THR, at least one of the plurality of second via holes H2 may pass through each of the plurality of lower barrier layers LB1, LB2, and LB3.

In some embodiment, the density of the plurality of first via holes H1 and the plurality of second via holes H2 on the pad region THR may be substantially equivalent to the density of the plurality of first via holes H1 and the plurality of second via holes H2 on the cell region CR. The sum of the area of the plurality of first via holes H1 and the area of the plurality of second via holes H2 per unit area on the pad region THR may be substantially equivalent to the sum of the area of the plurality of first via holes H1 and the area of the plurality of second via holes H2 per unit area on the cell region CR.

In an embodiment, in at least one of the plurality of lower barrier layers LB1, LB2, and LB3, the density of the plurality of first via holes H1 and the plurality of second via holes H2 on the pad region THR may be substantially equivalent to the density of the plurality of first via holes H1 and the plurality of second via holes H2 on the cell region CR. In an embodiment, the density of the plurality of first via holes H1 in each of the plurality of lower barrier layers LB1, LB2, and LB3 on the pad region THR may be substantially equivalent to the density of the plurality of first via holes H1 and the plurality of second via holes H2 in a corresponding one of the plurality of lower barrier layers LB1, LB2, and LB3 on the cell region CR.

In an embodiment, like the embodiment of FIG. 1 to FIG. 6, the density of the plurality of first via holes H1 on the pad region THR may be greater than the density of the plurality of first via holes H1 on the cell region CR. Accordingly, the density of the plurality of second via holes H2 on the pad region THR may be smaller than the density of the plurality of second via holes H2 on the cell region CR. The sum of the areas of the plurality of first via holes H1 per unit area on the pad region THR may be greater than the sum of the areas of the plurality of first via holes H1 per unit area on the cell region CR. The sum of the areas of the plurality of second via holes H2 per unit area on the pad region THR may be smaller than the sum of the areas of the plurality of second via holes H2 per unit area on the cell region CR.

For example, the number of the plurality of second via holes H2 per unit area on the pad region THR may be smaller than the number of the plurality of second via holes H2 per unit area on the cell region CR. In an embodiment, the average diameter of the plurality of second via holes H2 on the pad region THR may be smaller than the average diameter of the plurality of second via holes H2 on the cell region CR.

In an embodiment, a plurality of second via holes H2 may be disposed on the cell region CR and the pad region THR, and the density of the plurality of via holes H1 and H2 on the pad region THR may be substantially equivalent to the density of the plurality of via holes H1 and H2 on the cell region CR. Accordingly, the concentration of protons (H⁺) diffused in the circuit element PTR positioned on the pad region THR may be substantially equivalent to the concentration of protons (H⁺) diffused in the circuit element PTR positioned on the cell region CR. Therefore, the circuit element PTR may exhibit uniform performance, and the reliability of the semiconductor device may be improved.

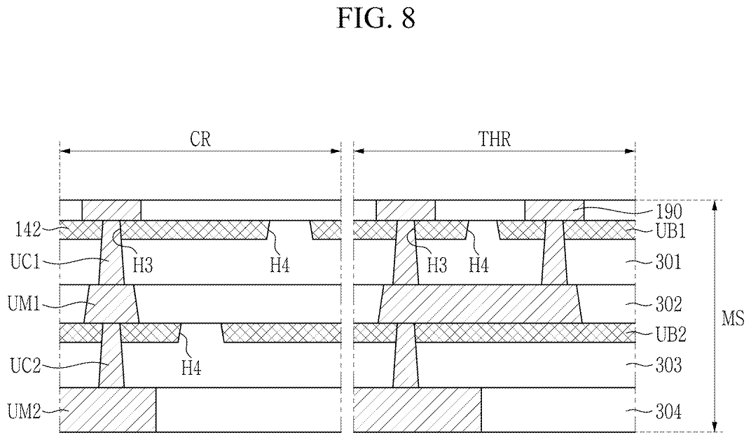

FIG. 8 is a cross-sectional view showing a first barrier structure of a semiconductor device according to some embodiments.

A semiconductor device according to an embodiment shown in FIG. 8 is the same as most of the semiconductor device according to the embodiment shown in FIG. 1 to FIG. 6 so that the description thereof is omitted and differences are mainly described. The same reference numerals are used for the same constituent elements as the previous embodiment. In the present embodiment, the second barrier structure US is partially different from the previous embodiment in that it includes a plurality of via holes H3 and H4, which will be described below.

Referring to FIG. 8, the cell structure CELL of the semiconductor device according to some embodiments may include a first substrate 100, a gate stacking structure 120, a channel structure CH, a channel pad 144, a separation structure 146, a cell wire part 180, and a second barrier structure US. The second barrier structure US may include a plurality of upper barrier layers UB1 and UB2, and a plurality of upper interlayer insulating layers 301, 302, 303, and 304 sequentially stacked on the bottom surface of the bit line BL in the third direction (the Z direction).

The plurality of upper barrier layers UB1 and UB2 of the previous embodiment may not include the plurality of second via holes H2.

Referring to FIG. 8, the second barrier structure US of the semiconductor device according to some embodiments may further include a plurality of via holes H3 and H4.

On the cell region CR and the pad region THR, the second barrier structure US may further include the plurality of third via holes H3. On the cell region CR and pad region THR, the second barrier structure US may further include a plurality of fourth via holes H4.

The plurality of third via holes H3 and the plurality of fourth via holes H4 may penetrate at least part of the second barrier structure US. The plurality of third via holes H3 and the plurality of fourth via holes H4 may pass through any one of the plurality of upper barrier layers UB1 and UB2. For example, as shown in FIG. 8, on the cell region CR and the pad region THR, the plurality of third via holes H3 may pass through the first upper barrier layer UB1 and the second upper barrier layer UB2. On the cell region CR and the pad region THR, the plurality of fourth via holes H4 may pass through the second upper barrier layer UB2. The present invention, however, is not limited thereto. In an embodiment, at least one of the plurality of third via holes H3 and at least one of the plurality of fourth via holes H4 may pass through each of the plurality of upper barrier layers UB1 and UB2.

In an embodiment, the plurality of fourth via holes H4 may be a dummy via hole for transferring protons (H⁺) to circuit elements of the peri structure PERI. In an embodiment, the plurality of third via holes H1 may be a via hole for electrically connecting between the circuit element of the peri structure PERI and the upper wires UM1 and UM2.

In an embodiment, the side surfaces of the plurality of third via holes H3 and the plurality of fourth via holes H4 may have an inclined taper shape with respect to the front surface of the second substrate 200. This may be due to characteristics of the process for forming the plurality of third via holes H3 and the plurality of fourth via holes H4 in a direction approaching the front surface of the first substrate 100. The present invention, however, is not limited thereto. In an embodiment, the side surfaces of the plurality of third via holes H3 and the plurality of fourth via holes H4 may have an inverted tapered shape inclined with respect to the front surface of the second substrate 200. In an embodiment, the side surfaces of the plurality of third via holes H3 and the plurality of fourth via holes H4 may include a vertical plane with respect to the front surface of the second substrate 200.

In an embodiment, the density of the plurality of third via holes H3 and the plurality of second via holes H2 on the pad region THR may be substantially equivalent to the density of the plurality of third via holes H3 and the plurality of fourth via holes H4 on the cell region CR. That is, the sum of the area of the plurality of third via holes H3 and the area of the plurality of second via holes H2 per unit area on the pad region THR may be substantially equivalent to the sum of the area of the plurality of third via holes H3 and the area of the plurality of fourth via holes H4 per unit area on the cell region CR.

In an embodiment, in at least one of the plurality of lower barrier layers LB1, LB2, and LB3, the density of the plurality of third via holes H3 and the plurality of second via holes H2 on the pad region THR may be substantially equivalent to the density of the plurality of third via holes H3 and the plurality of fourth via holes H4 on the cell region CR. In an embodiment, in each of the plurality of lower barrier layers LB1, LB2, and LB3, the density of the plurality of third via holes H3 on the pad region THR may be substantially equivalent to the densities of the plurality of third via holes H3 and the plurality of fourth via holes H4 on the cell region CR.

In an embodiment, similarly to the embodiment of FIG. 1 to FIG. 6, the density of the plurality of third via holes H3 on the pad region THR may be greater than the density of the plurality of third via holes H3 on the cell region CR. Accordingly, the density of the plurality of fourth via holes H4 on the pad region THR may be smaller than the density of the plurality of fourth via holes H4 on the cell region CR. The sum of the areas of the plurality of third via holes H3 per unit area on the pad region THR may be greater than the sum of the areas of the plurality of third via holes H3 per unit area on the cell region CR. The sum of the areas of the plurality of fourth via holes H4 per unit area on the pad region THR may be smaller than the sum of the areas of the plurality of fourth via holes H4 per unit area on the cell region CR.

For example, the number of plurality of fourth via holes H4 per unit area on the pad region THR may be smaller than the number of plurality of fourth via holes H4 per unit area on the cell region CR. In an embodiment, the average diameter of the plurality of fourth via holes H4 on the pad region THR may be smaller than an average diameter of the plurality of fourth via holes H4 on the cell region CR.

In an embodiment, the second barrier structure US may include the plurality of second via holes H2 on the cell region CR and the pad region THR. The present invention, however, is not limited thereto. For example, the second barrier structure US may include the plurality of second via holes H2 on the cell region CR and may not include the plurality of second via holes H2 on the pad region THR.

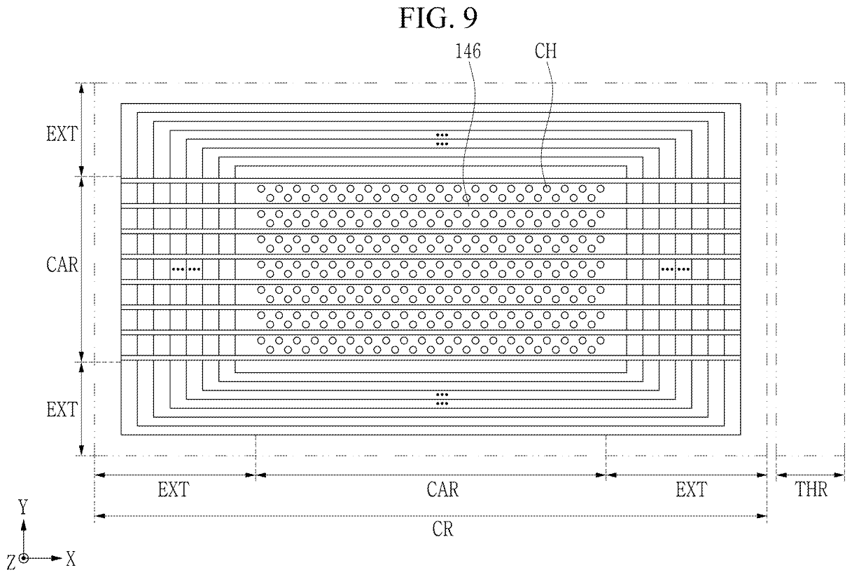

FIG. 9 is a top plan view schematically showing a semiconductor device according to some embodiments.

A semiconductor device according to an embodiment shown in FIG. 9 is the same as most of the semiconductor device according to the embodiment shown in FIG. 1 to FIG. 6 so that the description thereof is omitted and differences are mainly described. The same reference numerals are used for the same constituent elements as the previous embodiment. In the present embodiment, the arrangement of the pad region THR is partially different from that of the previous embodiment, which will be described below.

Referring to FIG. 9, the pad region THR may be positioned outside the extending region EXT. For example, when viewed in a plan view, the pad region THR may be positioned on one side of the extending region EXT (e.g., one side in the first direction (the X direction)). On the pad region THR, a source contact 186 and an input/output contact 188 may be positioned.

In an embodiment, on the cell region CR, the first barrier structure LS may include a plurality of second via holes H2. On the cell region CR and the pad region THR, the first barrier structure LS may include the plurality of second via holes H2.

In an embodiment, the first barrier structure LS on the cell region CR may include the plurality of second via holes H2. The density of the plurality of first via holes H1 on the pad region THR may be substantially equivalent to the density of the plurality of via holes H1 and H2 on the cell region CR. Accordingly, the concentration of protons (H⁺) diffused in the circuit element PTR positioned on the pad region THR may be substantially equivalent to the concentration of protons (H⁺) diffused in the circuit element PTR positioned on the cell region CR. Therefore, the circuit element PTR may exhibit uniform performance, and the reliability of the semiconductor device may be improved.

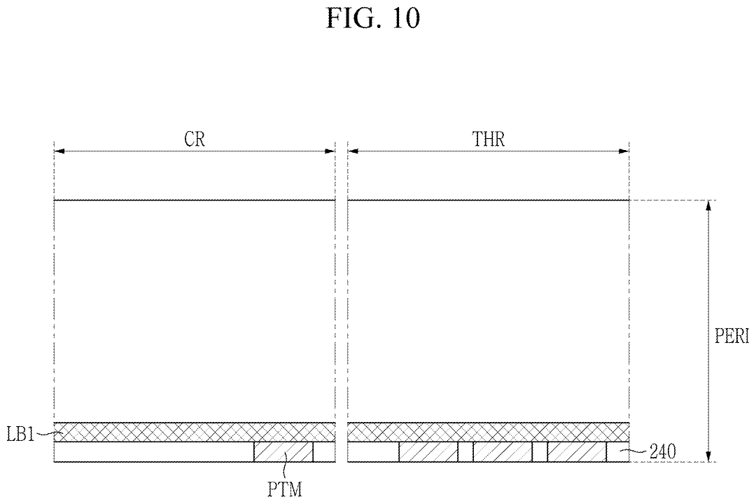

In the following, a manufacturing method of the semiconductor device according to an embodiment will be described with reference to FIG. 10 to FIG. 24.

FIG. 10 to FIG. 24 are intermediate-level views for explaining a manufacturing method of a semiconductor memory device according to an embodiment. For reference, FIG. 10 to FIG. 24 are the views of the intermediate steps to explain the manufacturing method of the semiconductor memory device shown in FIG. 2, and are the drawings corresponding to FIG. 5. For better understanding and ease of description, descriptions of overlapping contents with those described using FIG. 1 to FIG. 6 may be omitted.

Referring to FIG. 10, on a cell region CR and a pad region THR, a first lower barrier layer LB1 may be formed on a circuit element wire PTM and an inter-wire insulation layer 240. For example, the first lower barrier layer LB1 may include or may be formed of silicon nitride. The present invention, however, is not limited thereto. In an embodiment, the first lower barrier layer LB1 may include at least one of silicon carbonitride and silicon oxynitride.

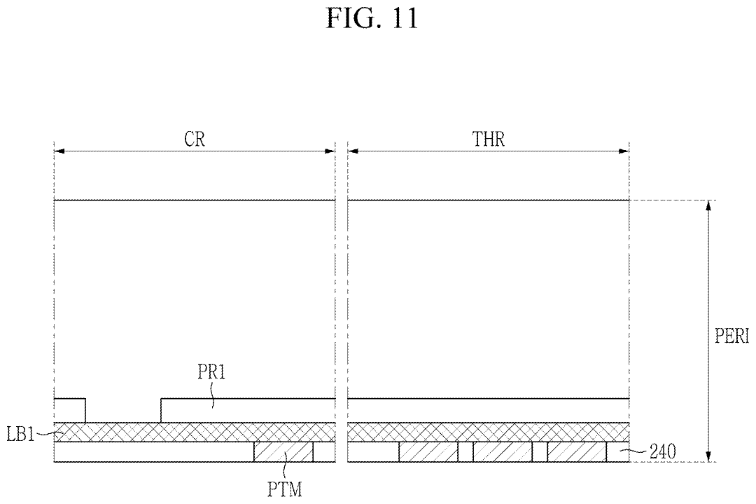

Referring to FIG. 11, on the cell region CR, a first photoresist PR1 may be formed on the first lower barrier layer LB1. The first photoresist PR1 may include or may be formed of a photosensitive material. The opening of the first photoresist PR1 may not overlap the circuit element wire PTM in the third direction (the Z direction).

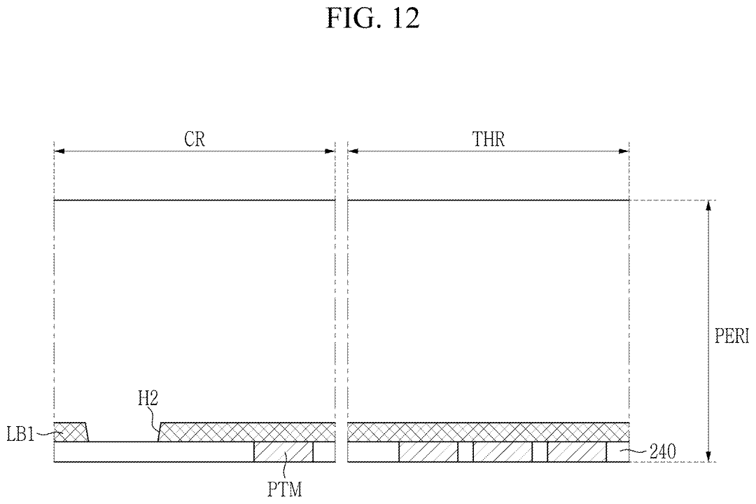

Referring to FIG. 12, on the cell region CR, a plurality of second via holes H2 may be formed by removing a part of the first lower barrier layer LB1 by a photolithography process using the first photoresist PR1 as a mask.

The plurality of second via holes H2 may be spaced apart from the circuit element wire PTM. The plurality of second via holes H2 may not overlap the circuit element wire PTM in the third direction (the Z direction). For example, the plurality of second via holes H2 of the first lower barrier layer LB1 may be spaced apart from the circuit element wire PTM. For example, a separation distance D1 between the plurality of second via holes H2 and the first lower wire LM1 in the elongation direction of the second substrate 200 may be 100 nm or more. At the separation distance D1 which is smaller than 100 nm, the material forming the first lower wire LM1 may be diffused through the plurality of second via holes H2.

The plurality of second via holes H2 may expose the upper surface of the inter-wire insulation layer 240.

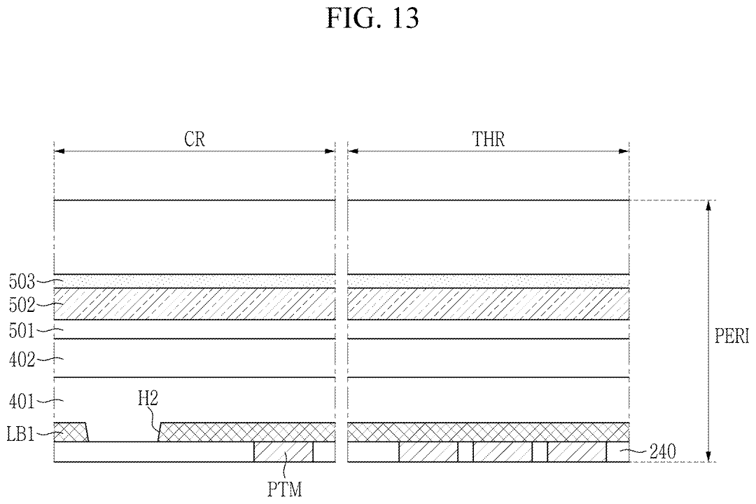

Referring to FIG. 13, on the cell region CR and the pad region THR, first and second lower interlayer insulating layers 401 and 402 may be formed on the first lower barrier layer LB1. The first and second lower interlayer insulating layers 401 and 402 may be formed of the same material, and a boundary between the first and second lower interlayer insulating layers 401 and 402 may not exist.

In an embodiment, the first lower interlayer insulating layer 401 may be filled in the plurality of second via holes H2. For example, the first lower interlayer insulating layer 401 may be positioned within the plurality of second via holes H2. Accordingly, a part of the first lower interlayer insulating layer 401 may contact the inter-wire insulation layer 240.

First to third etch stop layers 501, 502, and 503 may be formed on the first and second lower interlayer insulating layers 401 and 402. The first and third etch stop layers 501 and 503 may include or may be formed of silicon oxynitride. The second etch stop layer 502 may include or may be formed of a spin on hardmask (SOH). The present invention, however, is not limited thereto.

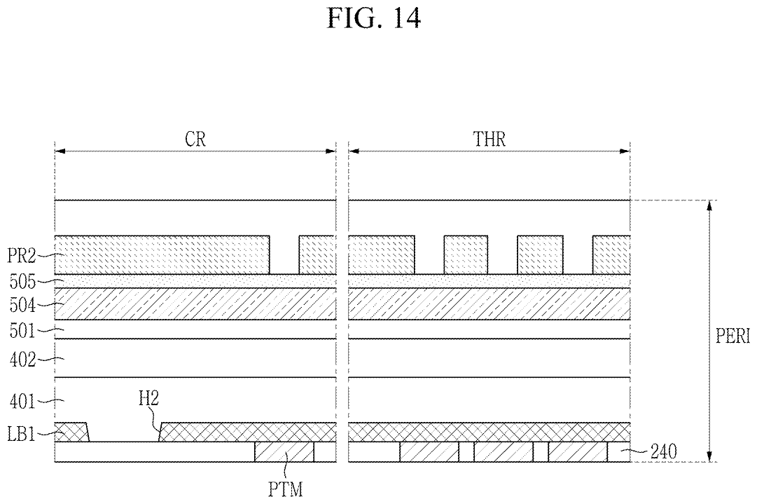

Referring to FIG. 14, on the cell region CR and the pad region THR, a second photoresist PR2 may be formed on the third etch stop layer 503. The second photoresist PR2 may include or may be formed of a photosensitive material. The ratio of the opening of the second photoresist PR2 per unit area on the cell region CR may be smaller than the ratio of the opening of the second photoresist PR2 per unit area on the pad region THR. The present invention, however, is not limited thereto.

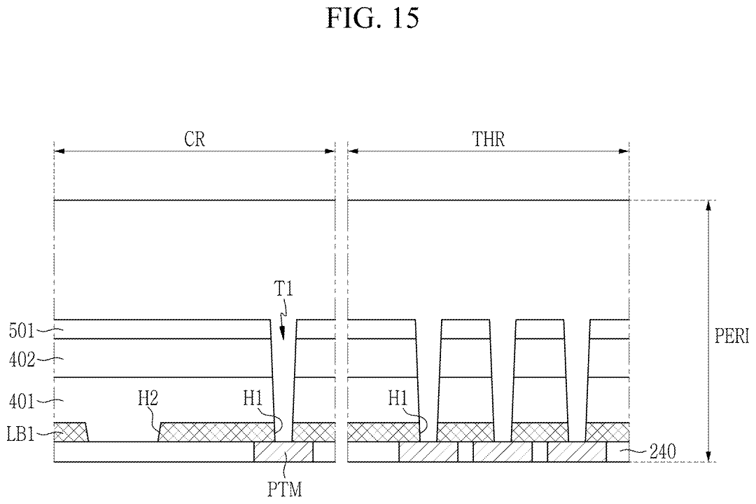

Referring to FIG. 15, on the cell region CR and the pad region THR, by a photolithography process using the second photoresist PR2 as a mask, a first trench T1 may be formed by removing at least part of the first lower barrier layer LB1, the first and the second lower interlayer insulating layers 401 and 402, and the first etch stop layer 501.

As the first trench T1 is formed, a plurality of first via holes H1 may be formed in the first lower barrier layer LB1. In an embodiment, the sum of the areas of the plurality of first via holes H1 per unit area on the pad region THR may be greater than the sum of the areas of the plurality of first via holes H1 per unit area on the cell region CR. In an embodiment, the density of the plurality of first via holes H1 on the pad region THR may be substantially equivalent to the density of the plurality of first via holes H1 on the cell region CR and the density of the plurality of second via holes H2 on the cell region CR. The sum of the areas of the plurality of first via holes H1 per unit area on the pad region THR may be substantially equivalent to the sum of the areas of the plurality of first via holes H1 and the areas of the plurality of second via holes H2 per unit area on the cell region CR.

Next, the second photoresist PR2, and the second and third etch stop layers 502 and 503 may be removed.

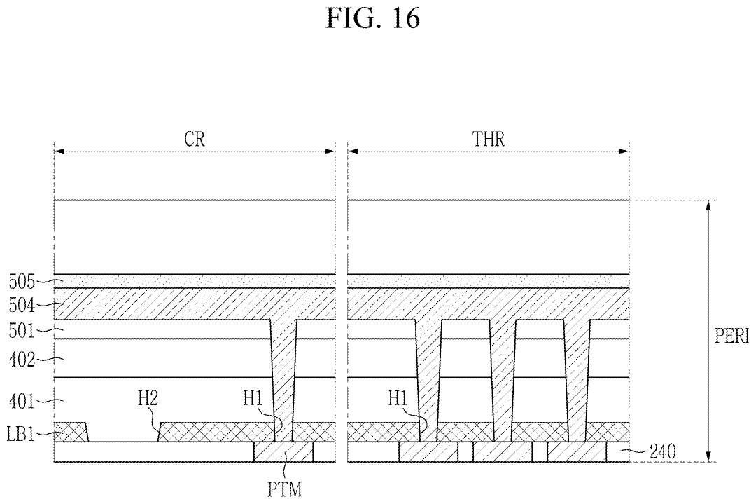

Referring to FIG. 16, on the cell region CR and the pad region THR, fourth and fifth etch stop layers 504 and 505 may be sequentially formed on the first trench T1 and the first etch stop layer 501. For example, the fourth etch stop layer 504 may include or may be formed of SOH. The fifth etch stop layer 505 may include or may be formed of silicon oxynitride. The fourth etch stop layer 504 may fill the inside of the first trench T1. The fourth etch stop layer 504 may fill the inside of the plurality of first via holes H1.

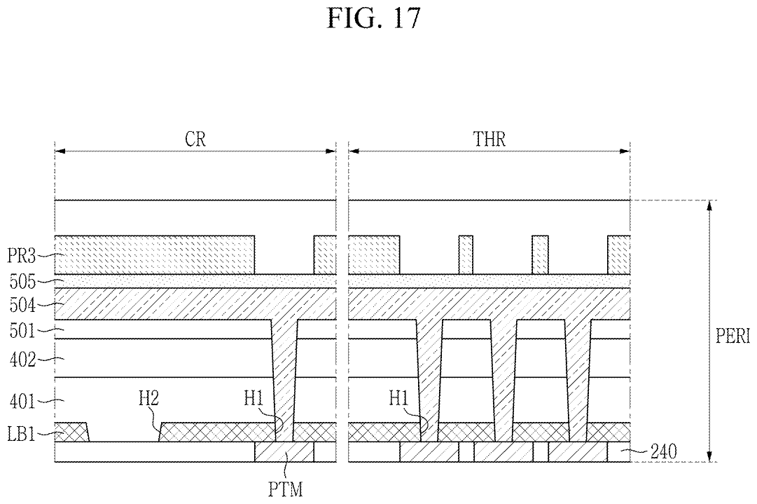

Referring to FIG. 17, on the cell region CR and the pad region THR, a third photoresist PR3 may be formed on the fifth etch stop layer 505. The third photoresist PR3 may include or may be formed of a photosensitive material. The ratio of the openings of the third photoresist PR3 per unit area on the cell region CR may be smaller than the ratio of the openings of the third photoresist PR3 per unit area on the pad region THR. The present invention, however, is not limited thereto.

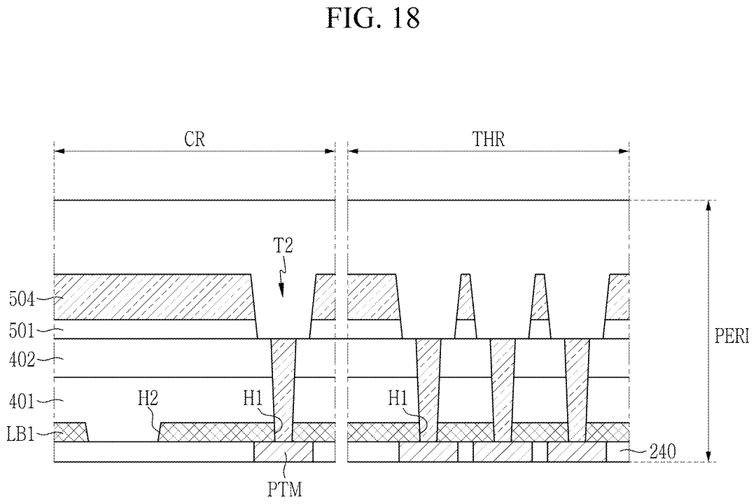

Referring to FIG. 18, on the cell region CR and the pad region THR, a second trench T2 is formed by removing at least part of the first etch stop layer 501, the fourth and fifth etch stop layers 504 and 505 by a photolithography process using the third photoresist PR3 as a mask. Next, the third photoresist PR3 and the fifth etch stop layer 505 may be removed, and the sidewall of the first etch stop layer 501, the sidewall and one surface of the fourth etch stop layer 504, and a part of the upper surface of the second lower interlayer insulating layer 402 may be exposed by the second trench T2. In an embodiment, the sum of the areas of the second trench T2 per unit area on the pad region THR may be greater than the sum of the areas of the second trench T2 per unit area on the cell region CR.

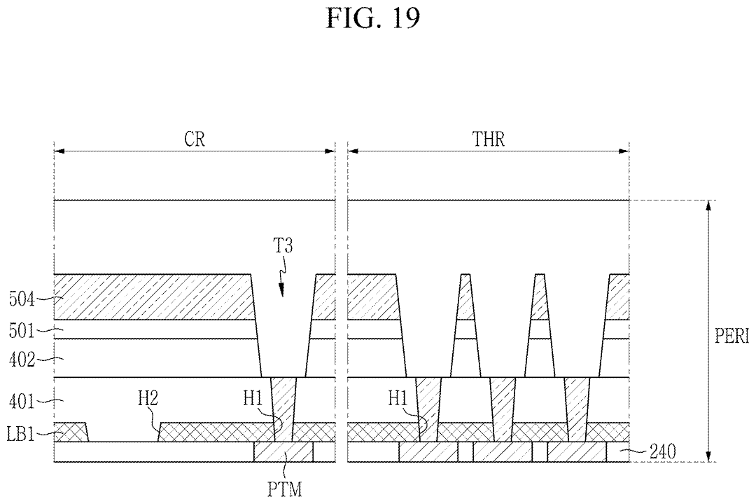

Referring to FIG. 19, on the cell region CR and the pad region THR, a third trench T3 may be formed by removing at least a part of the second lower interlayer insulating layer 402 along the profile of the sidewall of the second trench T2. Accordingly, the sidewall of the second lower interlayer insulating layer 402 and a portion of the upper surface of the first lower interlayer insulating layer 401 may be exposed.

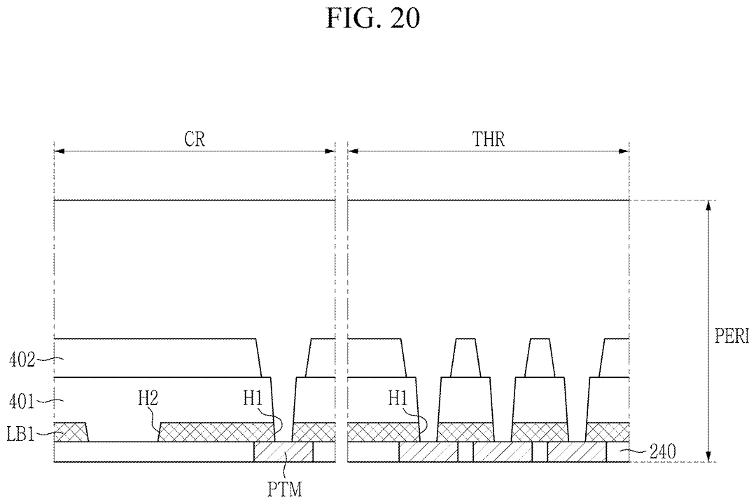

Referring to FIG. 20, on the cell region CR and the pad region THR, the fourth etch stop layer 504 may be removed. For example, a portion of the fourth etch stop layer 504 positioned on the first etch stop layer 501 and a portion of the fourth etch stop layer 504 positioned within the third trench T3 may be removed together. Accordingly, a plurality of first via holes H1 may be exposed. Subsequently, the first etch stop layer 501 may be removed.

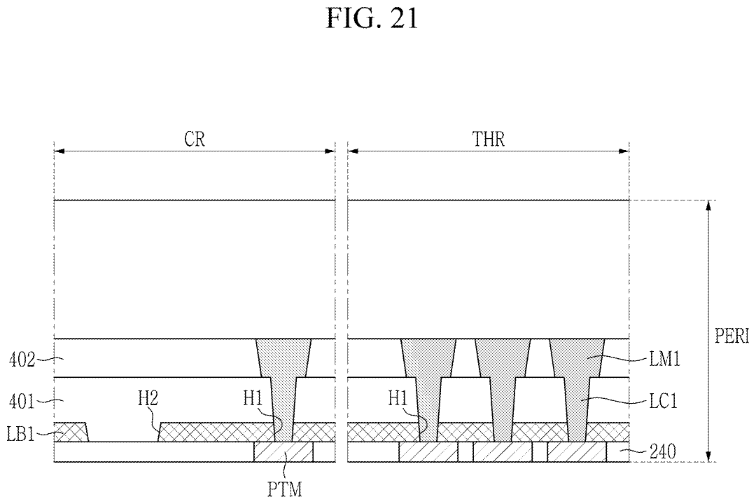

Referring to FIG. 21, on the cell region CR and the pad region THR, a first lower contact via LC1 and a first lower wire LM1 may be formed in the exposed third trench T3. The first lower contact via LC1 and the first lower wire LM1 may be formed by copper (Cu) plating.

In an embodiment, a first lower contact via LC1 may be formed in the first lower interlayer insulating layer 401. A first lower wire LM1 may be formed within the second lower interlayer insulating layer 402. The first lower contact via LC1 and the first lower wire LM1 may be integrally formed without a boundary therebetween. The present invention, however, is not limited thereto.

The process of forming the first lower contact via LC1 and the first lower wire LM1 may be formed through a planarization process such as a chemical mechanical process(CMP), so that the upper surface of the conductive and the upper surface of the second lower interlayer insulating layer 402 are positioned on the same plane after forming a conductive material layer on the second lower interlayer insulating layer 402.

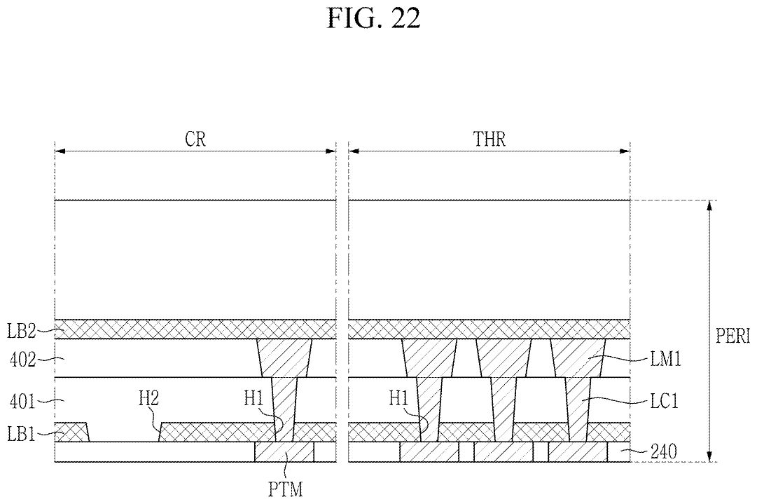

Referring to FIG. 22, on the cell region CR and the pad region THR, the second lower interlayer insulating layer 402 and the first lower wire LM1 may be formed on the second lower barrier layer LB2. For example, the second lower barrier layer LB2 may include or may be formed of silicon nitride. The present invention, however, is not limited thereto. In an embodiment, the second lower barrier layer LB2 may include or may be formed of at least one of silicon carbon oxide and silicon oxynitride.

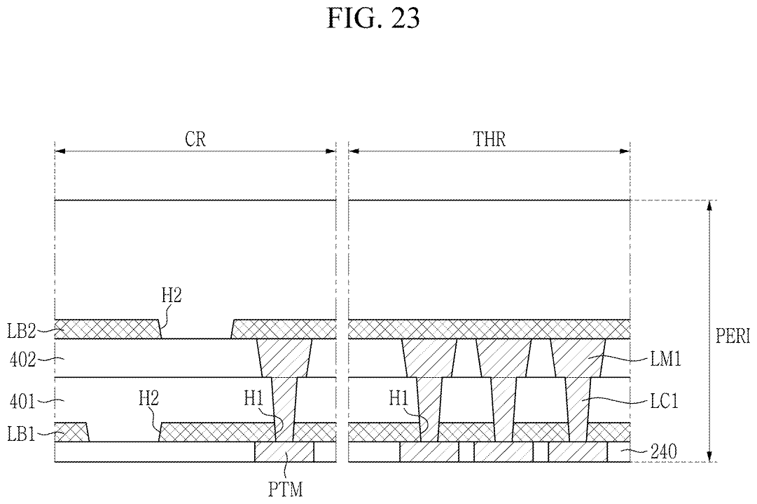

Referring to FIG. 23, on the cell region CR, a plurality of second via holes H2 may be formed in the second lower barrier layer LB2. Since the process of forming the plurality of second via holes H2 in the second lower barrier layer LB2 is substantially equivalent to the process of forming the plurality of second via holes H2 in the first lower barrier layer LB1, the description thereof will be omitted.

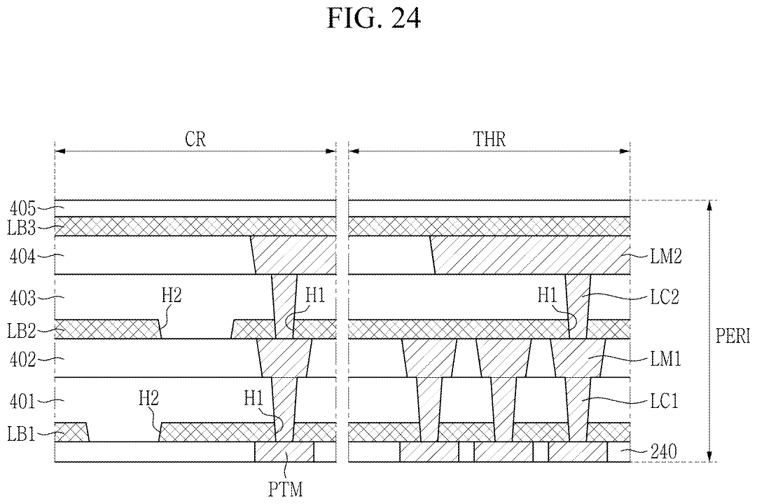

Referring to FIG. 24, first, third and fourth lower interlayer insulating layers 403 and 404 may be formed on the second lower barrier layer LB2. Next, a plurality of etch stop layers may be formed on the fourth lower interlayer insulating layer 404 and a photoresist may be formed on the plurality of etch stop layers. By using a photolithography process using a photoresist as a mask, a second lower contact via LC2 and a second lower wire LM2 may be formed. In some embodiments, a plurality of first via holes H1 may be formed in the second lower barrier layer LB2. Since the process of forming the second and third lower barrier layers LB2 and LB3, the second lower wire LM2, and the second lower contact via LC2 is substantially to the same as the process of forming the first lower barrier layer LB1, the first lower wire LM1, and the first lower contact via LC1 of the semiconductor device according to an embodiment of FIG. 13 to FIG. 22, the description thereof is omitted.

After that, a heat treatment process (alloy) may be performed. Accordingly, proton (H⁺) may be diffused to the circuit element PTR through the plurality of first via holes H1 and the plurality of second via holes H2 of the plurality of lower barrier layers LB1, LB2, and LB3.

In the following, an electronic system including the semiconductor device according to an embodiment will be described with reference to FIG. 25 to FIG. 27.

FIG. 25 is a view schematically showing an electronic system including a semiconductor device according to an embodiment.

As shown in FIG. 25, an electronic system 1000 according to an embodiment may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive device (SSD device), a universal serial bus (USB), a computing system, a medical device, or a communication device, including at least one semiconductor device 1100.

The semiconductor device 1100 may be a non-volatile memory device, for example, the NAND flash memory device as described with reference to FIG. 1 to FIG. 6. The semiconductor device 1100 may include a first structure 1100F and a second structure 1100S on the first structure 1100F. In an embodiment, the first structure 1100F may be positioned next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each memory cell strings CSTR may include lower transistors LT1 and LT2 adjacent to the common source line CSL, upper transistors UT1 and UT2 adjacent to the bit line BL, and a plurality of memory cell transistors MCT positioned between the lower transistors LT1 and LT2, and the upper transistors UT1 and UT2.

The number of lower transistors LT1 and LT2 and the number of upper transistors UT1 and UT2 may be variously changed according to embodiments.

In an embodiment, the lower transistors LT1 and LT2 may include a ground selection transistor, and upper transistors UT1 and UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wire 1115 extending from the second structure 1100S to the first structure 1100F. The bit line BL may be electrically connected to the page buffer 1120 through a second connection wire 1125 extending from the first structure 1100F to the second structure 1100S.

In the first structure 1100F, the decoder circuit 1110 and the page buffer 1120 may execute a control operation on at least one memory cell transistor selected from among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 extending from the first structure 1100F to the second structure 1100S.

The controller 1200 may include a processor 1210, a NAND controller 1220, and a host interface 1230. According to an embodiment, the electronic system 1000 may include a plurality of semiconductor devices 1100, and the controller 1200 may control the plurality of semiconductor devices 1100.

The processor 1210 may control the overall operation of the electronic system 1000 including the controller 1200. The processor 1210 may operate according to a predetermined firmware, and may access the semiconductor device 1100 by controlling the NAND controller 1220. The NAND controller 1220 may include a NAND interface 1221 that processes communication with the semiconductor device 1100. Through the NAND interface 1221, a control instruction for control the semiconductor device 1100, data to be recorded to the memory cell transistor MCT of the semiconductor device 1100, data to be read from the memory cell transistor MCT of the semiconductor device 1100 may be transmitted. The host interface 1230 may provide a communication function between the electronic system 1000 and an external host. When a control instruction is received from an external host through the host interface 1230, the processor 1210 may control the semiconductor device 1100 in response to the control instruction.

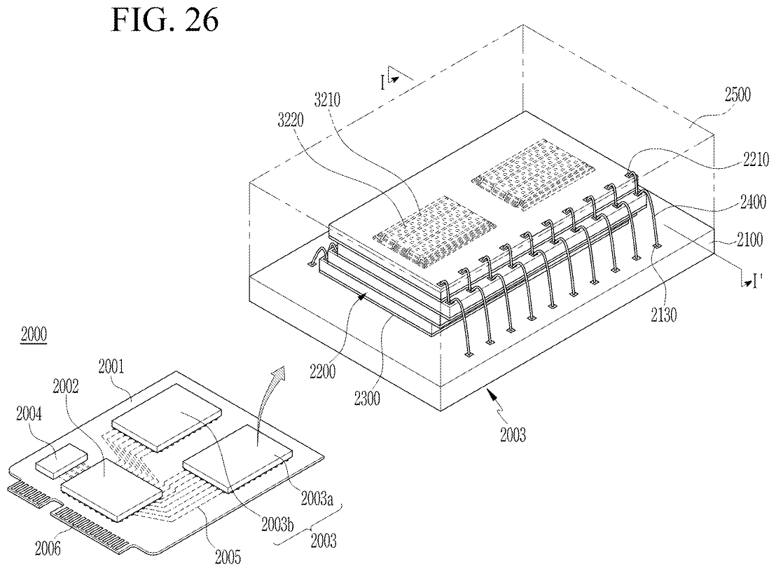

FIG. 26 is a perspective view schematically illustrating an electronic system including a semiconductor device according to an embodiment.

As shown in FIG. 26, an electronic system 2000 according to an embodiment may include a main substrate 2001, a controller 2002 mounted to the main substrate 2001, one or more semiconductor package 2003, and a dynamic random access memory (DRAM) 2004. The semiconductor package 2003 and the DRAM 2004 may be connected to the controller 2002 to each other by a wire pattern 2005 formed on the main substrate 2001.

The main substrate 2001 may include a connector 2006 including a plurality of pins coupled to an external host. The number and arrangement of the plurality of pins in the connector 2006 may vary depending on a communication interface between the electronic system 2000 and the external host. In an embodiment, the electronic system 2000 may communicate with the external host depending on any one of interfaces such as universal serial bus (USB), peripheral component interconnect express (PCI-Express), serial advanced technology attachment (SATA), universal flash storage (UFS) M-Phy, and the like. In an embodiment, the electronic system 2000 may operate by a power supplied from an external host through the connector 2006. The electronic system 2000 may further include a power management integrated circuit (PMIC) that distributes the power supplied from the external host to the controller 2002 and the semiconductor package 2003.

The controller 2002 may write a data to the semiconductor package 2003 or read a data from the semiconductor package 2003, and may improve the operation speed of the electronic system 2000.

The DRAM 2004 may be a buffer memory for mitigating a speed difference between the semiconductor package 2003, which is a data storage space, and an external host. The DRAM 2004 included in the electronic system 2000 may also operate as a kind of a cache memory, and may provide a space for temporarily storing a data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may be semiconductor packages including a plurality of semiconductor chips 2200, respectively. Each of the first and second semiconductor packages 2003a and 2003b may include a package substrate 2100, a semiconductor chip 2200 on the package substrate 2100, an adhesive layer 2300 positioned on the bottom surface of each semiconductor chip 2200, a connection structure 2400 electrically connecting the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 22. Each semiconductor chip 2200 may include a gate stacking structure 3210 and a channel structure 3220. The semiconductor chip 2200 may include the semiconductor device described with reference to FIG. 1 to FIG. 6.

In an embodiment, the connection structure 2400 may be a bonding wire electrically connecting the input/output pad 2210 and the package upper pad 2130. Accordingly, in each of the first and second semiconductor packages 2003a and 2003b, the semiconductor chips 2200 may be electrically connected to each other by using a bonding wire method, and may be electrically connected to the package upper pad 2130 of the package substrate 2100. According to an embodiment, in each of the first and second semiconductor packages 2003a and 2003b, the semiconductor chip 2200 may be electrically connected to each other by a connection structure including a through electrode (e.g., through silicon via (TSV)) instead of the connection structure 2400 of the bonding wire method.

In an embodiment, the controller 2002 and the semiconductor chip 2200 may be included in one package. For example, the controller 2002 and the semiconductor chip 2200 may be mounted on a separate interposer substrate different from the main substrate 2001, and the controller 2002 and the semiconductor chip 2200 may be connected by a wire formed in the interposer substrate.

FIG. 27 is a cross-sectional view schematically illustrating a semiconductor package according to an embodiment.

FIG. 27 describes an embodiment of the semiconductor package 2003 of FIG. 26, and conceptually represents a region cut along a cutting line I-I′ of the semiconductor package 2003 of FIG. 26.

Referring to FIG. 27, in the semiconductor package 2003A, each semiconductor chip 2200 may include a semiconductor substrate 4010, a first structure 4100 on the semiconductor substrate 4010, and a second structure 4200 jointed to the first structure 4100 by a wafer bonding method on the first structure 4100.

The first structure 4100 may include a peripheral circuit region including a peripheral wire 4110 and a first junction structure 4150. The second structure 4200 may include a common source line 4205, a gate stacking structure 4210 between the common source line 4205 and the first structure 4100, a channel structure 4220 and a separation structure 4230 passing through the gate stacking structure 4210, and a second junction structure 4250 electrically connected to the channel structure 4220 and a word line (e.g., the word line WL of FIG. 18) of the gate stacking structure 4210. For example, the second junction structure 4250 may be electrically connected to the channel structure 4220 and the word line WL, respectively, through the bit line 4240 electrically connected to the channel structure 4220 and a gate connection wire electrically connected to the word line WL. The first junction structure 4150 of the first structure 4100 and the second junction structure 4250 of the second structure 4200 may be jointed while contacting with each other. The junction portion of the first junction structure 4150 and the second junction structure 4250 may be formed of, for example, copper (Cu).

In the semiconductor chip 2200 or the semiconductor device according to an embodiment, the cell region CR and the pad region THR include the plurality of second via holes H2, and the density of the plurality of via holes H1 and H2 on the pad region THR may be substantially equivalent to the density of the plurality of via holes H1 and H2 on the cell region CR. Accordingly, the concentration of protons (H⁺) diffused in the circuit element PTR positioned on the pad region THR may be substantially equivalent to the concentration of protons (H⁺) diffused in the circuit element PTR positioned on the cell region CR. Therefore, the circuit element PTR may exhibit uniform performance, and the reliability of the semiconductor device may be improved.

Each of the semiconductor chips 2200 may further include an input/output pad 2210 and an input/output connection wire 4265 under the input/output pad 2210. The input/output connection wire 4265 may be electrically connected to a part of the second junction structure 4250.

In an embodiment, the plurality of semiconductor chips 2200 in the semiconductor package 2003A may be electrically connected to each other by a connection structure 2400 in a form of a bonding wire. In an embodiment, the plurality of semiconductor chips 2200 or the plurality of parts constituting the plurality of semiconductor chips may be electrically connected with each other by a connection structure including a through electrode.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

10: semiconductor device
CELL: cell structure
PERI: peri structure
100: first substrate
120: gate stacking structure
CH: channel structure
200: second substrate
LS: first barrier structure
US: second barrier structure

What is claimed is:

1. A semiconductor device comprising:
a peripheral structure; and
a cell structure stacked on the peripheral structure,
wherein the cell structure includes:
a first substrate including a pad region and a cell region including a cell array region and an extending region, wherein the first substrate includes a first surface and a second surface opposite to the first surface, and wherein second surface faces the peripheral structure;
a gate stacking structure including a plurality of gate electrodes and a plurality of interlayer insulating layers alternately stacked on the second surface of the first substrate;
a channel structure disposed on the cell array region and penetrating the plurality of gate electrodes and the plurality of interlayer insulating layers;
a plurality of gate contacts disposed on the extending region and connected to the plurality of gate electrodes, respectively;
a cell insulation layer positioned over the second surface of the first substrate and covering the gate stacking structure; and
an input/output contact disposed on the pad region and penetrating the cell insulation layer,
wherein the peripheral structure includes:
a second substrate electrically connected to the first substrate;
a plurality of circuit elements positioned on the second substrate;
a first barrier structure positioned over the second substrate and including a plurality of lower barrier layers;
a plurality of first via holes disposed on the cell region and the pad region and penetrating at least one of the plurality of lower barrier layers;
a plurality of second via holes disposed on the cell region and penetrating at least one of the plurality of lower barrier layers; and
a plurality of contact vias positioned within the plurality of first via holes and connected to the plurality of circuit elements, and
wherein, in at least one lower barrier layer of the plurality of lower barrier layers, a sum of areas of at least one of the plurality of first via holes per unit area on the pad region is equal to a sum of areas of at least one of the plurality of first via holes on the cell region and areas of the plurality of second via holes per unit area on the cell region.

2. The semiconductor device of claim 1,
wherein the sum of the areas of the at least one of the plurality of first via holes per unit area on the pad region is greater than a sum of areas of the at least one of the plurality of first via holes per unit area on the cell region.

3. The semiconductor device of claim 1, wherein:
the plurality of lower barrier layers of the first barrier structure include
a first lower barrier layer, and
a second lower barrier layer positioned on the first lower barrier layer;
the plurality of first via holes are formed in the first lower barrier layer and the second lower barrier layer and the plurality of second via holes are formed in the first lower barrier layer and the second lower barrier layer;
a sum of areas of at least one first via hole among the plurality of first via holes passing through the first lower barrier layer per unit area on the pad region is equal to a sum of areas of at least one first via hole among the plurality of first via holes and at least second via hole among the plurality of second via holes passing through the first lower barrier layer per unit area on the cell region; and
a sum of areas of at least one first via hole among the plurality of first via holes passing through the second lower barrier layer per unit area on the pad region is equal to a sum of areas of at least one first via hole among the plurality of first via holes and at least second via hole among the plurality of second via holes passing through the second lower barrier layer per unit area on the cell region.

4. The semiconductor device of claim 1, wherein:
the peripheral structure further includes a plurality of lower wires, each lower wire of the plurality of lower wires being positioned on a bottom surface of a corresponding one of the plurality of lower barrier layers and connected to a corresponding one of the plurality of contact vias;
the plurality of lower wires, when viewed in a plan view, overlap the plurality of first via holes; and
the plurality of lower wires, when viewed in the plan view, are spaced apart from the plurality of second via holes.

5. The semiconductor device of claim 4,
wherein the plurality of second via holes are spaced apart from the plurality of lower wires in an elongation direction of the second substrate along which the cell region and the pad region are arranged and which is parallel to the first surface of the first substrate.

6. The semiconductor device of claim 5,
wherein a separation distance between one of the plurality of lower wires and one of the plurality of second via holes adjacent thereto in the elongation direction corresponds to a shortest distance therebetween in the elongation direction, and
wherein the separation distance is 100 nm or more.

7. The semiconductor device of claim 4, wherein:
at least a portion of each of the plurality of lower wires and at least a portion of each of the plurality of contact vias include copper; and
the plurality of lower barrier layers include at least one of silicon nitride, silicon carbonitride, and silicon oxynitride.

8. The semiconductor device of claim 4, wherein:
the first barrier structure further includes a plurality of lower interlayer insulating layers alternately stacked with the plurality of lower barrier layers; and
the plurality of lower interlayer insulating layers are positioned within the plurality of second via holes.

9. The semiconductor device of claim 8, wherein:
a side of each of the plurality of lower wires is surrounded by a corresponding lower interlayer insulating layer of the plurality of lower interlayer insulating layers; and
a bottom surface of each of the plurality of lower wires contacts a lower interlayer insulating layer, below the corresponding lower interlayer insulating layer, of the plurality of lower interlayer insulating layers.

10. The semiconductor device of claim 1,
wherein the cell structure includes:
a second barrier structure positioned between the gate stacking structure and the first barrier structure and including a plurality of upper barrier layers;
a plurality of third via holes disposed on the cell region and the pad region and penetrating the plurality of upper barrier layers;
a plurality of fourth via holes disposed on the cell region and penetrating the plurality of upper barrier layers; and
a plurality of contact vias positioned within the plurality of third via holes, and
wherein in at least one upper barrier layer of the plurality of upper barrier layers in the second barrier structure, a sum of areas of the plurality of third and fourth via holes per unit area on the pad region is equal to a sum of areas of the plurality of third and fourth via holes on the cell region.

11. A semiconductor device comprising:
a peripheral structure; and
a cell structure stacked on the peripheral structure,
wherein the cell structure includes:
a first substrate including a pad region and a cell region including a cell array region and an extending region, wherein the first substrate includes a first surface and a second surface opposite to the first surface, and wherein the second surface faces the peripheral structure;
a gate stacking structure including a plurality of gate electrodes and a plurality of interlayer insulating layers alternately stacked on the second surface of the first substrate;
a channel structure disposed on the cell array region and penetrating the plurality of gate electrodes and the plurality of interlayer insulating layers;
a plurality of gate contacts disposed on the extending region and connected to the plurality of gate electrodes, respectively;
a cell insulation layer positioned over the second surface of the first substrate and covering the gate stacking structure; and
an input/output contact disposed on the pad region and penetrating the cell insulation layer,
wherein the peripheral structure includes:
a second substrate electrically connected to the first substrate;
a plurality of circuit elements positioned on the second substrate;
a first barrier structure positioned over the second substrate and including a plurality of lower barrier layers;
a plurality of first via holes disposed on the cell region and the pad region and penetrating at least one of the plurality of lower barrier layers;
a plurality of second via holes disposed on the cell region and the pad region and penetrating at least one of the plurality of lower barrier layers; and
a plurality of contact vias positioned within the plurality of first via holes and connected to the plurality of circuit elements,
wherein, in at least one lower barrier layer of the plurality of lower barrier layers, a sum of areas of at least one of the plurality of second via holes per unit area on the cell region is greater than a sum of areas of at least one of the plurality of second via holes per unit area on the pad region.

12. The semiconductor device of claim 11,
wherein at least one of a number of the plurality of second via holes per unit area and an average diameter of the plurality of second via holes is greater on the cell region than on the pad region.

13. The semiconductor device of claim 11,
wherein a sum of areas of at least one of the plurality of first via holes per unit area on the pad region is less than the sum of areas of at least one of the plurality of first via holes per unit area on the cell region.

14. The semiconductor device of claim 13, wherein:
wherein a sum of areas of the at least one of the plurality of first via holes and the at least one of the plurality of second via holes per unit area on the pad region is equal to a sum of areas of the at least one of the plurality of first via holes and the at least one of the plurality of second via holes per unit area on the cell region.

15. The semiconductor device of claim 11, wherein:
wherein the cell structure includes:
a second barrier structure positioned between the gate stacking structure and the first barrier structure and including a plurality of upper barrier layers;
a plurality of third via holes disposed on the cell region and the pad region and penetrating the plurality of upper barrier layers;
a plurality of fourth via holes disposed on the cell region and penetrating the plurality of upper barrier layers; and
a plurality of contact vias positioned within the plurality of third via holes, and
wherein, in at least one upper barrier layer of the plurality of upper barrier layers in the second barrier structure, a sum of areas of the plurality of third via holes per unit area on the pad region is equal to a sum of areas of the plurality of third via holes per unit area on the cell region.

16. The semiconductor device of claim 15,
wherein a sum of areas of the plurality of third and fourth via holes per unit area on the pad region is equal to a sum of areas of the plurality of third and fourth via holes per unit area on the cell region.

17. The semiconductor device of claim 11, wherein:
the peripheral structure further includes a plurality of lower wires, each lower wire of the plurality of lower wires being positioned on a bottom surface of a corresponding one of the plurality of lower barrier layers and connected to a corresponding one of the plurality of contact vias;
the plurality of lower wires, when viewed in a plan view, overlap the plurality of first via holes; and
the plurality of lower wires, when viewed in the plan view, are spaced apart from the plurality of second via holes.

18. The semiconductor device of claim 17, wherein:
at least a portion of each of the plurality of lower wires and at least a portion of each of the plurality of contact vias include copper; and
the plurality of lower barrier layers include at least one of silicon nitride, silicon carbonitride, and silicon oxynitride.

19. An electron system comprising:
a main substrate;
a semiconductor device on the main substrate; and
a controller electrically connected to the semiconductor device on the main substrate,
wherein the semiconductor device includes a peripheral structure and a cell structure stacked on the peripheral structure,
wherein the cell structure includes:
a first substrate including a cell region including a pad region and a cell array region and an extending region, wherein the first substrate includes a first surface and a second surface opposite to each other, and wherein the second surface faces the peripheral structure;
a gate stacking structure including a plurality of gate electrodes and a plurality of interlayer insulating layers alternately stacked on the second surface of the first substrate;
a channel structure disposed on the cell array region and penetrating the plurality of gate electrodes and the plurality of interlayer insulating layers;
a plurality of gate contacts disposed on the extending region and connected to the plurality of gate electrodes, respectively;
a cell insulation layer positioned on the second surface of the first substrate and covering the gate stacking structure; and
an input/output contact disposed on the pad region and penetrating the cell insulation layer,
wherein the peripheral structure includes:
a second substrate electrically connected to the first substrate;
a plurality of circuit elements positioned on the second substrate;
a first barrier structure disposed on the second substrate and including a plurality of lower barrier layers;
a plurality of first via holes disposed on the cell region and the pad region and penetrating at least one of the plurality of lower barrier layers;
a plurality of second via holes disposed on the cell region and penetrating at least one of the plurality of lower barrier layers; and
a plurality of contact vias positioned within the plurality of first via holes and connected to the plurality of circuit elements, and
wherein, in at least one lower barrier layer of the plurality of lower barrier layers, a sum of areas of at least one of the plurality of first via holes per unit area on the pad region is equal to a sum of areas of at least one of the plurality of first via holes on the cell region and areas of the plurality of second via holes per unit area on the cell region.

20. The electron system of claim 19, wherein:
the peripheral structure further includes a plurality of lower wires, each lower wire of the plurality of lower wires being positioned on a bottom surface of a corresponding one of the plurality of lower barrier layers and connected to a corresponding one of the plurality of contact vias; and
the plurality of second via holes are spaced apart from the plurality of lower wires in an elongation direction of the second substrate along which the cell region and the pad region are arranged.
